(19) United States
(12) Patent Application Publication
(10) Pub. No.: US 2026/0314090 A1
(43) Pub. Date: Oct. 8, 2026

(54) PHOTODETECTION DEVICE AND ELECTRONIC APPARATUS

(71) Applicant: SONY SEMICONDUCTOR SOLUTIONS CORPORATION, KANAGAWA (JP)

(72) Inventor: KEN TOMITA, KANAGAWA (JP)

(21) Appl. No.: 19/480,330

(22) PCT Filed: Mar. 29, 2024
(86) PCT No.: PCT/JP2024/013198

§ 371 Date: Oct. 30, 2025

(30) Foreign Application Priority Data
May 22, 2023 (JP) 2023-083684

(51) Int. Cl. H10F 39/00; H10F 30/221; H10F 39/18

(52) U.S. Cl. CPC H10F 39/80373; H10F 30/221; H10F 39/182; H10F 39/8027; H10F 39/8033; H10F 39/8063; H10F 39/807; H10F 39/011

(57) ABSTRACT

Transconductance (gm) of a transfer transistor is increased. A photodetection device includes a semiconductor layer having a first surface and a second surface located opposite to each other in a thickness direction, a photoelectric conversion region provided in the semiconductor layer, the photoelectric conversion region being partitioned by an isolation region extending in the thickness direction of the semiconductor layer, and a transfer transistor including a gate electrode provided on a first surface side of the semiconductor layer in the photoelectric conversion region, the transfer transistor transferring signal charge obtained as a result of photoelectric conversion in the photoelectric conversion unit to a charge holding unit. The photoelectric conversion region includes a main body provided with the photoelectric conversion unit and the charge holding unit, and a protrusion protruding from the main body toward the isolation region in plan view, and the gate electrode of the transfer transistor is provided over the main body and the protrusion of the photoelectric conversion region.

### TECHNICAL FIELD

The present technology (a technology relating to the present disclosure) relates to a photodetection device and an electronic apparatus, and more particularly relates to a technology effective when applied to a photodetection device including transfer transistors in photoelectric conversion regions and an electronic apparatus including the photodetection device.

### BACKGROUND ART

A photodetection device such as a solid-state imaging device or a ranging device includes transfer transistors that transfer signal charge generated by photoelectric conversion units through photoelectric conversion to charge holding units. Patent Document 1 discloses a planar transfer transistor. Furthermore, Patent Document 2 discloses an imaging device in which a groove for shallow trench isolation (STI) is formed in a substrate, pinning of STI sidewalls is enhanced during accumulation by applying a voltage to an embedded polysilicon electrode embedded in the groove via an insulating film, and transfer of signal charge is improved during the transfer by applying voltages to pixel region p-wells and the embedded polysilicon electrode.

### CITATION LIST

### Patent Document

Patent Document 1: Japanese Patent Application Laid-open No. 2022-068751

Patent Document 2: Japanese Patent Application Laid-Open No. 2006-120804

### SUMMARY OF THE INVENTION

### Problems to be Solved by the Invention

Meanwhile, in recent years, high-resolution image sensors have been demanded in the market, and development of image sensors with a reduced pixel size has been advanced.

However, in order to reduce the pixel size, it is necessary to miniaturize photoelectric conversion regions and transfer transistors arranged in the photoelectric conversion regions, and transconductance (gm) of the transfer transistors decreases. Therefore, the present technology has been made focusing on isolation regions that partition the photoelectric conversion regions.

An object of the present technology is to provide a technique capable of improving transconductance (gm) of transfer transistors.

### Solutions to Problems

(1) A photodetection device according to an aspect of the present technology includes:
   a semiconductor layer having a first surface and a second surface located opposite to each other in a thickness direction;
   a photoelectric conversion region provided in the semiconductor layer, the photoelectric conversion region being partitioned by an isolation region extending in the thickness direction of the semiconductor layer; and
   a transfer transistor that transfers signal charge obtained as a result of photoelectric conversion in the photoelectric conversion unit to a charge holding unit.

The photoelectric conversion region includes a main body provided with the photoelectric conversion unit and the charge holding unit, and a protrusion protruding from the main body toward the isolation region in plan view, and the gate electrode of the transfer transistor is provided over the main body and the protrusion of the photoelectric conversion region.
(2) An electronic apparatus according to another aspect of the present technology includes:
   the photodetection device;
   an optical lens that forms an image of image light from a subject on an imaging surface of the detection device; and
   a signal processing circuit that performs signal processing on a signal output from the photodetection device.

### BRIEF DESCRIPTION OF DRAWINGS

FIG. 1 is a chip layout diagram illustrating a configuration example of a solid-state imaging device according to a first embodiment of the present technology.

FIG. 2 is a block diagram illustrating a configuration example of the solid-state imaging device according to the first embodiment of the present technology.

FIG. 3 is an equivalent circuit diagram illustrating a configuration example of a pixel and a pixel circuit according to the first embodiment of the present technology.

FIG. 4 is a plan view schematically illustrating a configuration example of a pixel block included in a pixel array unit of FIG. 1.

FIG. 5 is a longitudinal sectional view schematically illustrating a longitudinal sectional structure taken along section line a4-a4 in FIG. 4.

FIG. 6 is a plan view in which gate electrodes of transfer transistors in FIG. 4 are omitted.

FIG. 7 is a plan view schematically illustrating a planar pattern of one photoelectric conversion region included in the pixel block in FIG. 4.

FIG. 8 is a longitudinal sectional view schematically illustrating a longitudinal sectional structure taken along section line a7-a7 in FIG. 7.

FIG. 9 is a diagram for explaining configuration of a gate electrode of a transfer transistor.

FIG. 10 is a plan view schematically illustrating a step of a method for manufacturing the solid-state imaging device according to the first embodiment of the present technology.

FIG. 11 is a longitudinal sectional view schematically illustrating a longitudinal sectional structure taken along section line a10-a10 in FIG. 10.

FIG. 12 is a plan view schematically illustrating a step subsequent to FIG. 10.

FIG. 13A is a longitudinal sectional view schematically illustrating a longitudinal sectional structure taken along section line a12-a12 in FIG. 12.

FIG. 13B is a longitudinal sectional view schematically illustrating a longitudinal sectional structure taken along section line b12-b12 in FIG. 12.

FIG. 14A is a diagram schematically illustrating a step subsequent to FIG. 12, and is a longitudinal sectional view illustrating a longitudinal sectional structure at the same position as section line a12-a12 in FIG. 12.

FIG. 14B is a diagram schematically illustrating a step subsequent to FIG. 12, and is a longitudinal sectional view illustrating a longitudinal sectional structure at the same position as section line b12-b12 in FIG. 12.

FIG. 15 is a diagram schematically illustrating a step subsequent to FIG. 14A, and is a longitudinal sectional view illustrating a longitudinal sectional structure at the same position as section line b12-b12 in FIG. 12.

FIG. 16 is a diagram schematically illustrating a step subsequent to FIG. 15, and is a longitudinal sectional view illustrating a longitudinal sectional structure at the same position as section line b12-b12 in FIG. 12.

FIG. 17A is a diagram illustrating an example of a potential in a semiconductor layer immediately below a gate electrode in a conventional technique in which the gate electrode of a transfer transistor is provided in a photoelectric conversion region not including protrusions.

FIG. 17B is a diagram illustrating an example of a potential in a semiconductor layer immediately below a gate electrode in the first embodiment of the present technology in which the gate electrode of a transfer transistor is provided over a main body and protrusions of a photoelectric conversion region.

FIG. 18A is a plan view schematically illustrating Modification 1-1 of the first embodiment of the present technology.

FIG. 18B is a longitudinal sectional view schematically illustrating a longitudinal sectional structure taken along section line a18-a18 in FIG. 18A.

FIG. 19 is a plan view schematically illustrating Modification 1-2 of the first embodiment of the present technology.

FIG. 20 is a plan view schematically illustrating Modification 1-3 of the first embodiment of the present technology.

FIG. 21 is a plan view schematically illustrating Modification 1-4 of the first embodiment of the present technology.

FIG. 22 is a longitudinal section view schematically illustrating Modification 1-5 of the first embodiment of the present technology.

FIG. 23 is a plan view schematically illustrating a configuration example of a pixel block included in a pixel array unit in a solid-state imaging device according to a second embodiment of the present technology.

FIG. 24 is a longitudinal sectional view schematically illustrating a longitudinal sectional structure taken along section line a23-a23 in FIG. 22.

FIG. 25 is a plan view in which gate electrodes of transfer transistors in FIG. 23 are omitted.

FIG. 26 is a plan view schematically illustrating a configuration example of a pixel block included in a pixel array unit in a solid-state imaging device according to a second embodiment of the present technology.

FIG. 27 is a longitudinal sectional view schematically illustrating a longitudinal sectional structure taken along section line a26-a26 in FIG. 26.

FIG. 28 is a plan view schematically illustrating Modification 3-3 of a third embodiment of the present technology.

FIG. 29 is a plan view schematically illustrating Modification 3-4 of the third embodiment of the present technology.

FIG. 30 is a longitudinal sectional view schematically illustrating Modification 3-5 of the third embodiment of the present technology.

FIG. 31 is a diagram illustrating a configuration example of an electronic apparatus according to a fourth embodiment of the present technology.

### MODE FOR CARRYING OUT THE INVENTION

Embodiments of the present technology will be described in detail hereinafter with reference to the drawings.

Note that in the illustration of the drawings referred to in the following description, the same or similar portions are denoted by the same or similar reference signs. It should be noted that the drawings are schematic, and relationships between thicknesses and planar dimensions, ratios of thicknesses between layers, and the like are different from actual ones. Therefore, specific thicknesses and dimensions should be determined in consideration of the following description.

Furthermore, it is needless to say that the drawings include portions having different dimensional relationships and ratios. Furthermore, the effects described herein are merely illustrative and not limiting, and there may also be other effects.

Furthermore, the following embodiments illustrate devices and methods for implementing the technical idea of the present technology and are not intended to limit the configuration to those described below. That is, various modifications can be made to the technical idea of the present technology within the technical scope described in the claims.

Furthermore, definitions of directions such as up and down in the following description are merely for convenience of description and are not intended to limit the technical idea of the present technology. For example, it is a matter of course that when an object is observed by rotating the object by 90°, the up and down are converted into and read as left and right, and when the object is observed by rotating the object by 180°, the up and down are inverted and read.

Furthermore, in the following embodiments, in three directions orthogonal to each other in a space, a first direction and a second direction orthogonal to each other in the same plane are defined as an X direction and a Y direction, respectively, and a third direction orthogonal to the first direction and the second direction is defined as a Z direction. In the following embodiments, a thickness direction of a semiconductor layer 21 described later will be described as the Z direction.

### FIRST EMBODIMENT

In a first embodiment, an example where the present technology is applied, as a photodetection device, to a solid-state imaging device that is a back-illuminated complementary metal-oxide-semiconductor (CMOS) image sensor will be described.

Furthermore, in the first embodiment, a planar transfer transistor will be described as a transfer transistor.

### Overall Configuration of Solid-State Imaging Device

First, an overall configuration of a solid-state imaging device 1A will be described.

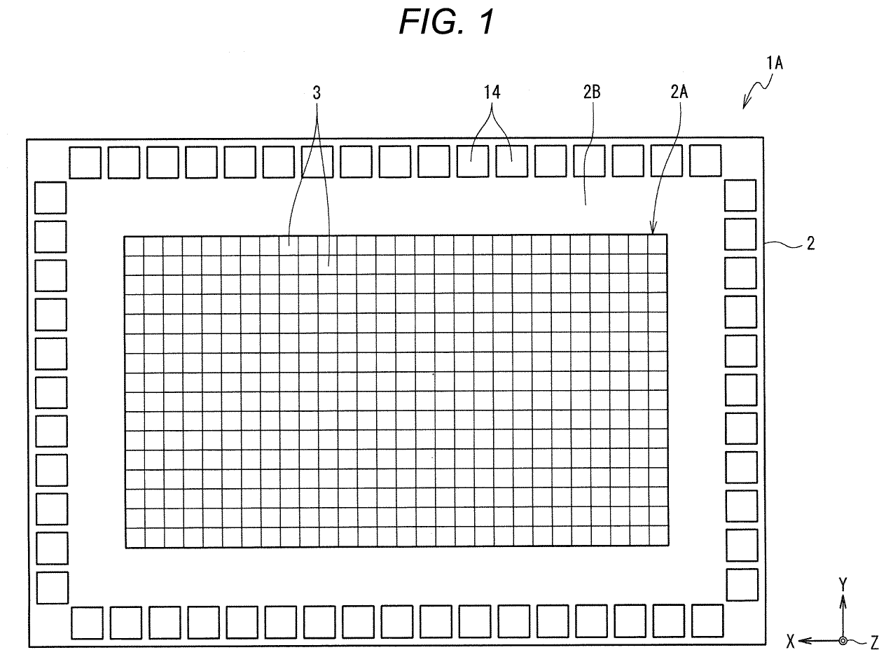

As illustrated in FIG. 1, the solid-state imaging device 1A according to the first embodiment of the present technology mainly includes a semiconductor chip 2 having a rectangular two-dimensional planar shape in plan view. That is, the solid-state imaging device 1A is mounted on the semiconductor chip 2, and the semiconductor chip 2 can be regarded as the solid-state imaging device 1A. As illustrated in FIG. 31, the solid-state imaging device 1A (101) receives image light (incident light 106) from a subject through an optical lens 102, converts an amount of the incident light 106 formed, as an image, on an imaging plane into an electrical signal for each pixel, and outputs the electrical signal as a pixel signal.

As illustrated in FIG. 1, the semiconductor chip 2 on which the solid-state imaging device 1A is mounted includes, in a two-dimensional plane including the X direction and the Y direction perpendicular to each other, a rectangular pixel array unit 2A provided in a central portion thereof and a peripheral portion 2B provided outside the pixel array unit 2A in such a way as to surround the pixel array unit 2A. A semiconductor wafer including the semiconductor layer 21 described later is diced into small pieces, each serving as a chip formation region, to form the semiconductor chip 2 in a manufacturing process. Configuration of the solid-state imaging device 1A, which will be described below, therefore, is substantially similar to that before the semiconductor wafer is diced into small pieces. That is, the present technology is applicable to both a semiconductor chip and a semiconductor wafer.

The pixel array unit 2A is, for example, a light receiving surface that receives light condensed by the optical lens (optical system) 102 illustrated in FIG. 31. A plurality of pixels 3 is then arranged in the pixel array unit 2A in a matrix in the two-dimensional plane including the X direction and the Y direction. In other words, the pixels 3 are repeatedly arranged in the X direction and the Y direction perpendicular to each other in the two-dimensional plane.

As illustrated in FIG. 1, a plurality of bonding pads 14 is arranged in the peripheral portion 2B. Each of the plurality of bonding pads 14 is arranged along each of four sides of the two-dimensional plane of the semiconductor chip 2, for example. Each of the plurality of bonding pads 14 functions as an input/output terminal that electrically connects the semiconductor chip 2 and an external device to each other.

### Logic Circuit

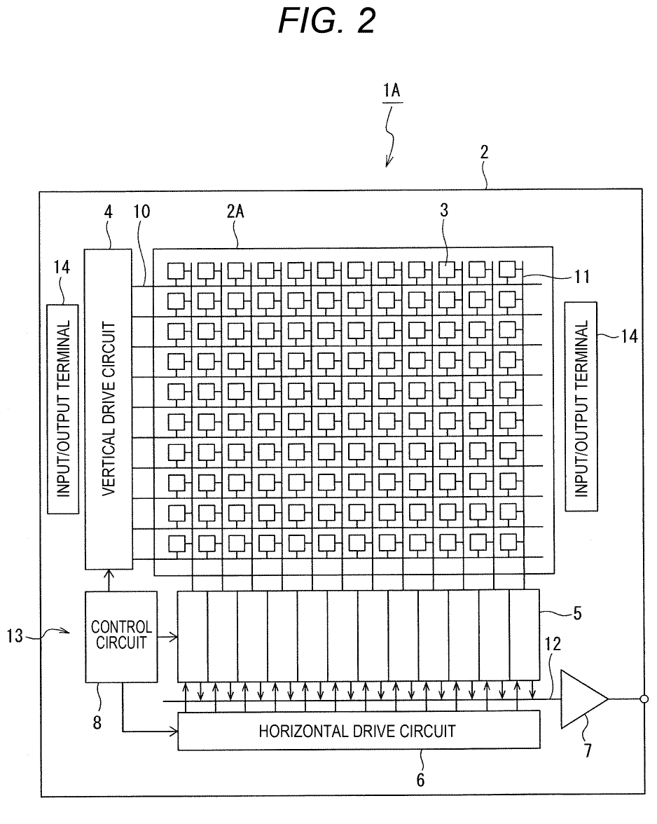

The semiconductor chip 2 includes a logic circuit 13 illustrated in FIG. 2. As illustrated in FIG. 2, the logic circuit 13 includes a vertical drive circuit 4, column signal processing circuits 5, a horizontal drive circuit 6, an output circuit 7, a control circuit 8, and the like. The logic circuit 13 includes, for example, a complementary MOS (CMOS) circuit including an n-channel metal-oxide-semiconductor field-effect transistor (MOSFET) and a p-channel MOSFET as field-effect transistors.

The vertical drive circuit 4 illustrated in FIG. 2 includes a shift register, for example. The vertical drive circuit 4 sequentially selects desired pixel drive lines 10, supplies pulses for driving the pixels 3 to the selected pixel drive lines 10, and drives the pixels 3 row by row. That is, the vertical drive circuit 4 selectively scans the individual pixels 3 in the pixel array unit 2A sequentially in a vertical direction row by row and supplies pixel signals from the pixels 3 based on signal charge generated by photoelectric conversion units of the pixels 3 in accordance with the amount of light received to the corresponding column signal processing circuits 5 through corresponding vertical signal lines 11.

The column signal processing circuit 5 illustrated in FIG. 2 is arranged, for example, for each column of the pixels 3, and performs signal processing such as noise removal for each pixel column on signals output from the pixels 3 of one row. For example, each column signal processing circuit 5 performs signal processing such as correlated double sampling (CDS) for removing pixel-specific fixed pattern noise, and analog-to-digital (AD) conversion.

The horizontal drive circuit 6 illustrated in FIG. 2 includes, for example, a shift register. The horizontal drive circuit 6 sequentially outputs horizontal scanning pulses to the column signal processing circuits 5 to sequentially select each of the column signal processing circuits 5, and causes each of the column signal processing circuits 5 to output pixel signals obtained as a result of signal processing to a horizontal signal line 12.

The output circuit 7 illustrated in FIG. 2 performs signal processing on the pixel signals sequentially supplied from each of the column signal processing circuits 5 through the horizontal signal line 12, and outputs the processed pixel signals. As the signal processing, for example, buffering, black level adjustment, column variation correction, various types of digital signal processing, and the like can be used.

The control circuit 8 illustrated in FIG. 2 generates clock signals and control signals as references for operations of the vertical drive circuit 4, the column signal processing circuits 5, the horizontal drive circuit 6, and the like on the basis of a vertical synchronization signal, a horizontal synchronization signal, and a master clock signal. The control circuit 8 then outputs the generated clock signals and control signals to the vertical drive circuit 4, the column signal processing circuits 5, the horizontal drive circuit 6, and the like.

### Pixel Block

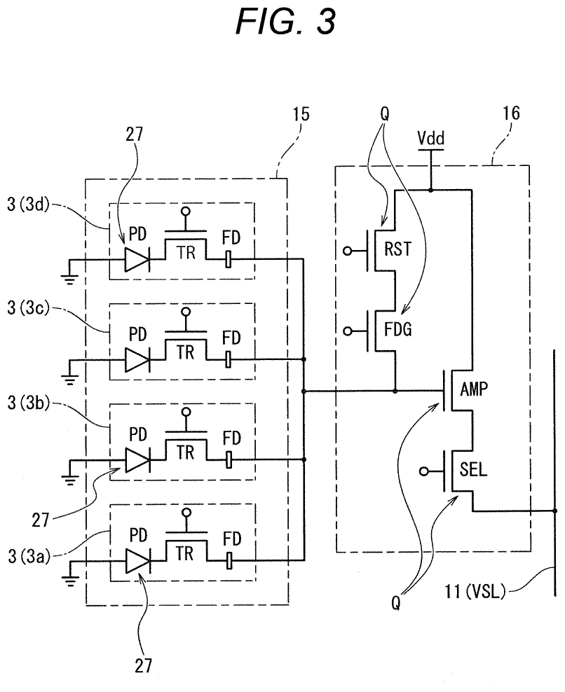

The semiconductor chip 2 includes a pixel block 15 and a pixel circuit (readout circuit) 16 illustrated in FIG. 3.

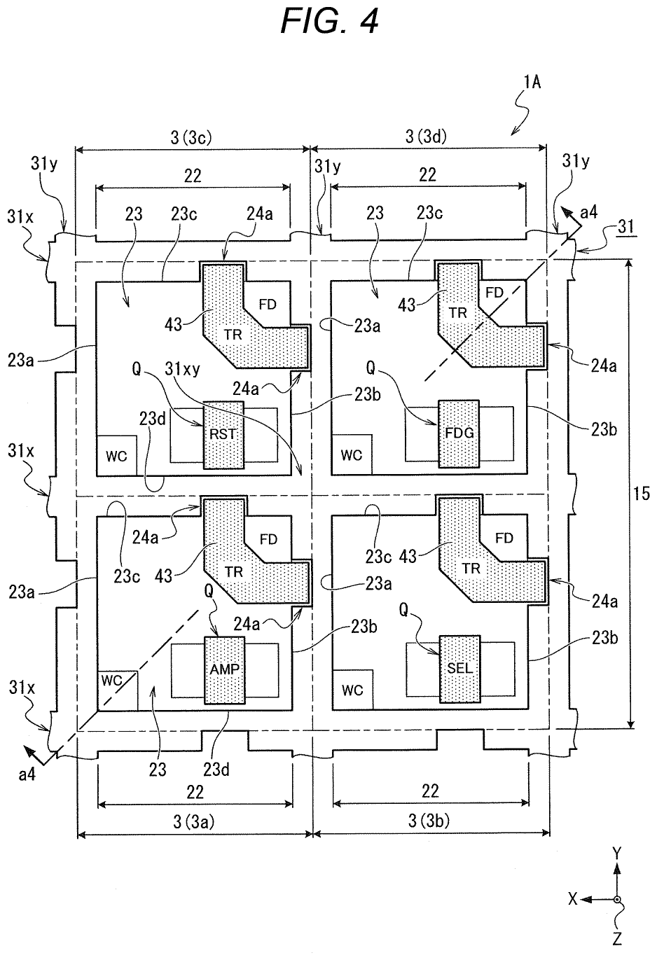

As illustrated in FIGS. 3 and 4, the pixel block 15 includes a plurality of pixels 3. The pixel block 15 of the first embodiment is not limited thereto, but includes, for example, four pixels 3 (3a, 3b, 3c, and 3d) arranged in a 2×2 arrangement in which two adjacent pixels are arranged side by side in each of the X direction and the Y direction in plan view as one unit. In FIGS. 3 and 4, one pixel block 15 is mainly illustrated, but the pixel block 15 is repeatedly arranged in each of the X direction and the Y direction to construct the pixel array unit 2A illustrated in FIG. 1.

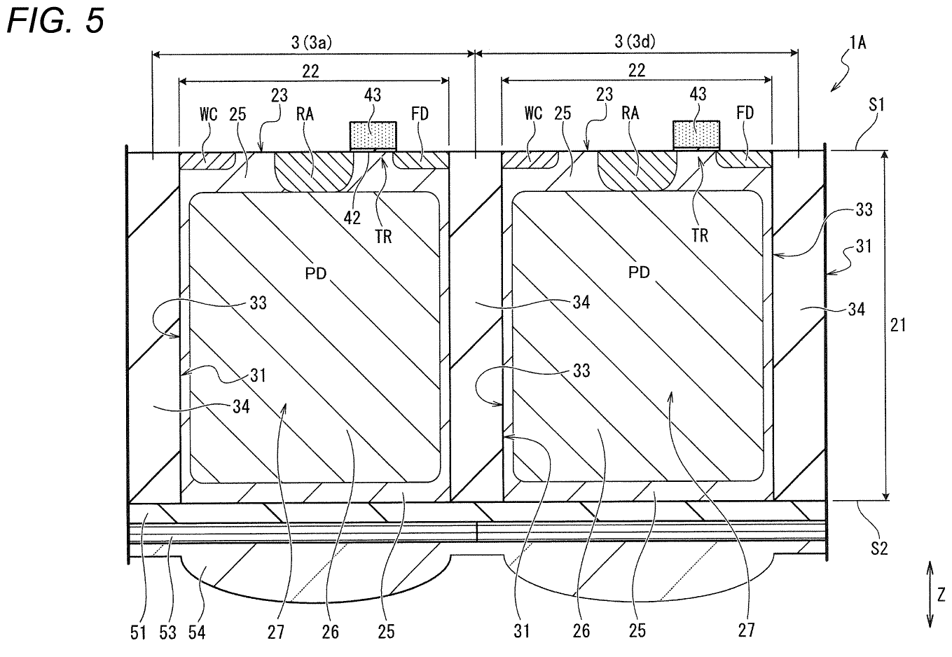

As illustrated in FIG. 3, each of the four pixels 3a, 3b, 3c, and 3d included in one pixel block 15 includes the same components. Specifically, each of the four pixels 3a, 3b, 3c, and 3d included in one pixel block 15 includes a photoelectric conversion unit 27, a floating diffusion region FD as a charge holding unit that holds (accumulates) signal charge generated by the photoelectric conversion unit 27 as a result of photoelectric conversion, and a transfer transistor TR that transfers, to the floating diffusion region FD, the signal charge generated by the photoelectric conversion unit 27 as a result of the photoelectric conversion. In addition, each of the four pixels 3a, 3b, 3c, and 3d included in one pixel block 15 further includes a photoelectric conversion region 22 of the semiconductor layer 21 illustrated in FIG. 5. As illustrated in FIG. 5, each of the photoelectric conversion unit 27, the floating diffusion region FD, and the transfer transistor TR is provided in the photoelectric conversion region 22.

### (Photoelectric Conversion Unit)

Each photoelectric conversion unit 27 illustrated in FIG. 3 includes, for example, a p-n junction type photodiode (PD), and generates signal charge according to the amount of light received. Furthermore, the photoelectric conversion unit 27 temporarily holds (accumulates) the generated signal charge.

The photoelectric conversion unit 27 has a cathode side electrically connected to a source region of the transfer transistor TR and an anode side electrically connected to a reference potential line (for example, ground).

### (Transfer Transistor)

The transfer transistor TR illustrated in FIG. 3 transfers the signal charge generated by the photoelectric conversion unit 27 as a result of the photoelectric conversion to the floating diffusion region FD. The transfer transistor TR has the source region electrically connected to the cathode side of the photoelectric conversion unit 27 and a drain region electrically connected to the floating diffusion region FD. A gate electrode of the transfer transistor TR is electrically connected to a transfer transistor drive line among the pixel drive lines 10 illustrated in FIG. 2.

### (Floating Diffusion Region)

Each floating diffusion region FD illustrated in FIG. 3A temporarily accumulates and holds the signal charge transferred from the photoelectric conversion unit 27 via the transfer transistor TR.

### Pixel Circuit

As illustrated in FIG. 3, an input side of the pixel circuit 16 is electrically connected to the floating diffusion region FD. The pixel circuit 16 of the first embodiment is provided for each pixel block 15, for example, and is shared by the four pixels 3 (3a, 3b, 3c, and 3d) included in one pixel block 15.

Here, in the first embodiment, as an example, a circuit configuration is employed in which one pixel circuit 16 is allocated to one pixel block 15 including four pixels 3 as one unit, but the circuit configuration to be employed is not limited to that in the first embodiment. For example, a circuit configuration in which one pixel circuit 16 is allocated to one pixel block 15 including two or more pixels 3 as one unit may be employed, or a circuit configuration in which one pixel circuit 16 is allocated to a plurality of pixel blocks 15 including a plurality of pixels 3 as one unit may be employed, instead. Alternatively, a circuit configuration in which one pixel circuit 16 is allocated to one pixel 3 may be employed.

An input stage of the pixel circuit 16 illustrated in FIG. 3 is electrically connected to the floating diffusion region FD of each of the four pixels 3 (3a, 3b, 3c, and 3d) included in one pixel block 15. The pixel circuit 16 then reads the signal charges held in the floating diffusion region FD of each of the four pixels 3 (3a, 3b, 3c, and 3d), and outputs a pixel signal based on the read signal charge. In other words, the pixel circuit 16 converts signal charge generated by the photoelectric conversion units 27 (photodiode PD) as a result of photoelectric conversion into pixel signals based on the signal charge and outputs the pixel signals.

As illustrated in FIG. 3, the pixel circuit 16 includes, but is not limited to, an amplification transistor AMP, a selection transistor SEL, a reset transistor RST, and a switching transistor FDG as pixel transistors Q, for example. The pixel transistor Q (AMP, SEL, RST, and FDG) and the above-described transfer transistor TR are configured as insulated gate field-effect transistors, for example, by metal-oxide-semiconductor field-effect transistors (MOSFETs) whose gate insulating films are silicon oxide (SiO₂) films. Alternatively, these pixel transistors may each be a metal-insulator-semiconductor FET (MISFET) whose gate insulating film is a silicon nitride (Si₃N₄) film or a multilayer film of a silicon nitride film and a silicon oxide film.

Among the pixel transistors Q (AMP, SEL, RST, and FDG) included in the pixel circuit 16, the selection transistor SEL, the reset transistor RST, and the switching transistor FDG mainly function as switching elements. The remaining amplification transistor AMP mainly functions as an amplification element.

The amplification transistor AMP illustrated in FIG. 3 has a source region electrically connected to a drain region of the selection transistor SEL and a drain region electrically connected to a power supply line Vdd and a drain region of the reset transistor RST. A gate electrode of the amplification transistor AMP is electrically connected to the floating diffusion region FD of each of the four pixels 3 (3a, 3b, 3c, and 3d) and a source region of the reset transistor RST.

The selection transistor SEL illustrated in FIG. 3 has a source region electrically connected to the vertical signal line 11 (VSL) and the drain region electrically connected to the source region of the amplification transistor AMP. A gate electrode of the selection transistor SEL is electrically connected to a selection transistor drive line among pixel drive lines 10 illustrated in FIG. 2.

The reset transistor RST illustrated in FIG. 3 has a source region electrically connected to a drain of the switching transistor FDG and the drain region electrically connected to the power supply line Vdd and the drain region of the amplification transistor AMP. A gate electrode of the reset transistor RST is electrically connected to a reset transistor drive line among the pixel drive lines 10 illustrated in FIG. 2.

The switching transistor FDG illustrated in FIG. 3 has the drain region electrically connected to the source region of the reset transistor RST, and the drain region electrically connected to the gate electrode of the amplification transistor AMP and the floating diffusion region FD of the pixel 3. The switching transistor FDG has a gate electrode electrically connected to a switching transistor drive line among the pixel drive lines 10 illustrated in FIG. 2.

Note that the selection transistor SEL and the Switching transistor FDG may be omitted as necessary.

In a case where the selection transistor SEL is omitted, the source region of the amplification transistor AMP is electrically connected to the vertical signal line 11 (VSL). Furthermore, in a case where the switching transistor FDG is omitted, the reset transistor RST has the source region electrically connected to the gate electrode of the amplification transistor AMP and the floating diffusion region FD.

When turned on, the transfer transistor TR illustrated in FIG. 3 transfers the signal charge generated by the photoelectric conversion unit 27 (photodiode PD) to the floating diffusion region FD.

When turned on, the reset transistor RST illustrated in FIG. 3 resets a potential (signal charge) of the floating diffusion region FD to a potential of the power supply line Vdd. The selection transistor SEL controls output timings of pixel signals from the pixel circuit 16.

The amplification transistor AMP illustrated in FIG. 3 generates a voltage signal corresponding to a level of the signal charge held in the floating diffusion region FD as the pixel signal. The amplification transistor AMP constitutes a source follower amplifier, and outputs a pixel signal indicating a voltage corresponding to the level of the signal charge generated by the photoelectric conversion unit 27 (photodiode PD). When the selection transistor SEL is turned on, the amplification transistor AMP amplifies the potential of the floating diffusion region FD, and outputs a voltage corresponding to the potential to the column signal processing circuit 5 via the vertical signal line (VSL) 11.

The switching transistor FDG illustrated in FIG. 3 controls charge holding of the floating diffusion region FD and adjusts an amplification factor of the voltage according to the potential amplified by the amplification transistor AMP.

While the solid-state imaging device 1A according to the first embodiment is in operation, the signal charge generated in the photoelectric conversion unit 27 of the pixel 3 is held (accumulated) in the floating diffusion region FD via the transfer transistor TR of the pixel 3. The signal charge held in the floating diffusion region FD is then read out by the pixel circuit 16 and applied to the gate electrode of the amplification transistor AMP of the pixel circuit 16. A vertical shift register supplies a horizontal line selection control signal to the gate electrode of the selection transistor SEL of the pixel circuit 16. Setting the selection control signal to a high (H) level then brings the selection transistor SEL into conduction to allow a current corresponding to the potential of the floating diffusion region FD amplified by the amplification transistor AMP to flow to the vertical signal line 11. Furthermore, setting a reset control signal to be applied to the gate electrode of the reset transistor RST of the pixel circuit 16 to the high (H) level brings the reset transistor RST into conduction to reset the signal charge accumulated in the floating diffusion region FD.

The photoelectric conversion units 27, the transfer transistors TR, and the floating diffusion regions FD illustrated in FIG. 3 are provided in the semiconductor layer 21 (see FIG. 5), which will be described later. Furthermore, although not limited to this, the pixel transistors Q (AMP, SEL, RST, and FDG) included in the pixel circuit 16 illustrated in FIG. 3, for example, are also provided in the semiconductor layer 21.

### Specific Configuration of Solid-State Imaging Device

Next, a specific configuration of the semiconductor chip 2 (solid-state imaging device 1A) will be described with reference to FIGS. 4 to 9.

In FIGS. 4 and 5, illustration of a multilayer wiring layer described later is omitted for easy viewing of the drawings. In addition, FIG. 1 illustrates a light incident surface side of the semiconductor chip 2, but FIG. 4 is a plan view of the semiconductor chip 2 as viewed from a side opposite to the light incident surface side (multilayer wiring layer side).

As illustrated in FIG. 5, the semiconductor chip 2 includes the semiconductor layer 21 having a first surface S1 and a second surface S2 located on opposite sides in a thickness direction (Z direction), an isolation region 31 extending in the thickness direction of the semiconductor layer 21, and photoelectric conversion regions 22 partitioned by the isolation region 31 and provided in the semiconductor layer 21.

In addition, the semiconductor chip 2 further includes transfer transistors TR that transfer the signal charge obtained by the photoelectric conversion units 27 as a result of photoelectric conversion to the n-type floating diffusion regions FD as charge holding units that hold signal charge.

Furthermore, although not illustrated, the semiconductor chip 2 further includes a multilayer wiring layer provided on a first surface S1 side of the semiconductor layer 21. Furthermore, the semiconductor chip 2 further includes, on a second surface S2 side of the semiconductor layer 21, a planarization film 51, optical filters 53, and microlenses (on-chip lenses) 54 sequentially provided from the second surface S2 side.

Here, the first surface S1 of the semiconductor layer 21 will also be referred to as a main surface or an element formation surface, and the second surface S2 will also be referred to as a back surface. The solid-state imaging device 1A according to the first embodiment then performs photoelectric conversion on incident light incident from the second surface S2 side of the semiconductor layer 21 by the photoelectric conversion units 27 (photodiodes PD) provided in the photoelectric conversion regions 22 of the semiconductor layer 21. In the first embodiment, therefore, the second surface S2 of the semiconductor layer 21 will also be referred to as a light incident surface.

As illustrated in FIG. 4, two of the four pixels 3 (3a, 3b, 3c, and 3d) included in one pixel block 15 are arranged in each of the X direction and the Y direction in plan view, and laid out in a 2×2 arrangement. That is, in the pixel array 2A illustrated in FIG. 1, a pixel block 15 including the four pixels 3 (3a, 3b, 3c, and 3d) as a unit is repeatedly arranged in each of the X direction and the Y direction.

### Planarization Film, Optical Filter, and Microlens

The planarization film 51 illustrated in FIG. 5 is provided on the second surface S2 side of the semiconductor layer 21 in such a way as to cover the second surface S2 of the semiconductor layer 21, and planarizes the second surface S2 side of the semiconductor layer 21.

The optical filter 53 and the microlens 54 illustrated in FIG. 5 are provided for each pixel 3. The optical filter 53 color-separates incident light incident from the light incident surface side (second surface S2 side) of the semiconductor chip 2. The microlens 54 condenses radiated light and allows the condensed light to efficiently enter the pixel 3.

### Semiconductor Layer

As illustrated in FIG. 5, the semiconductor layer 21 is provided with the isolation region 31 extending in the thickness direction (Z direction) of the semiconductor layer 21 and the photoelectric conversion regions 22 partitioned by the isolation region 31. The photoelectric conversion region 22 is provided for each pixel 3. As the semiconductor layer 21, a Si substrate, a SiGe substrate, an InGaAs substrate, or the like may be used. In the first embodiment, although not limited to this, a p-type semiconductor substrate including, for example, single crystal silicon is used as the semiconductor layer 21.

### Isolation Region

### (Planar Shape)

As illustrated in FIG. 4, the isolation region 31 includes first portions 31x extending in the X direction and second portions 31y extending in the Y direction in plan view. The isolation region 31 further includes an intersection portion (intersection point) where the first portion 31x and the second portion 31y intersect each other on the same plane. In the first embodiment, the first portions 31x and the second portions 31y are, for example, orthogonal to each other.

The first portion 31x is repeatedly arranged at a predetermined interval in the Y direction. In addition, the second portion 31y is repeatedly arranged at a predetermined interval in the X direction. That is, in the isolation region 31, a planar pattern in plan view is a lattice-shaped planar pattern.

As illustrated in FIG. 4, the isolation region 31 corresponding to one photoelectric conversion region 22 has, in plan view, a planar pattern that is a rectangular annular planar pattern (ring-shaped planar pattern), and surrounds the photoelectric conversion region 22. The isolation region 31 corresponding to one pixel block 15 is a composite planar pattern having a cross-shaped planar pattern in which the first portion 31x and the second portion 31y are arranged orthogonally to each other in the rectangular annular planar pattern.

As illustrated in FIG. 4, in the isolation region 31 corresponding to one pixel block 15, an intersection portion (intersection point) 31xy between the first portion 31x and the second portion 31y is located in a central portion of the pixel block 15. The photoelectric conversion regions 22 of the four pixels 3 (3a, 3b, 3c, and 3d) are then arranged in a matrix in such a way as to surround the intersection portion 31xy.

### (Cross-Sectional Shape)

As illustrated in FIG. 5, each isolation region 31 extends in the thickness direction (Z direction) of the semiconductor layer 21, and electrically and optically isolates two photoelectric conversion regions 22 adjacent to each other in plan view. The isolation region 31 is, for example, a dug type, that is, a so-called trench type, in which a dug portion 33 is formed in the semiconductor layer 21 to partition and isolate the photoelectric conversion region 22.

The isolation region 31 includes, but is not limited to, for example, the dug portion 33 extending over the first surface S1 and the second surface S2 of the semiconductor layer 21, and an isolation insulating film 34 provided in the dug portion 33. That is, the isolation region 31 extends over the first surface S1 and the second surface S2 of the semiconductor layer 21. As the isolation insulating film 34, for example, a silicon oxide film may be used. In the first embodiment, the dug portion 33 is embedded with, for example, the isolation insulating film 34.

### Photoelectric Conversion Region

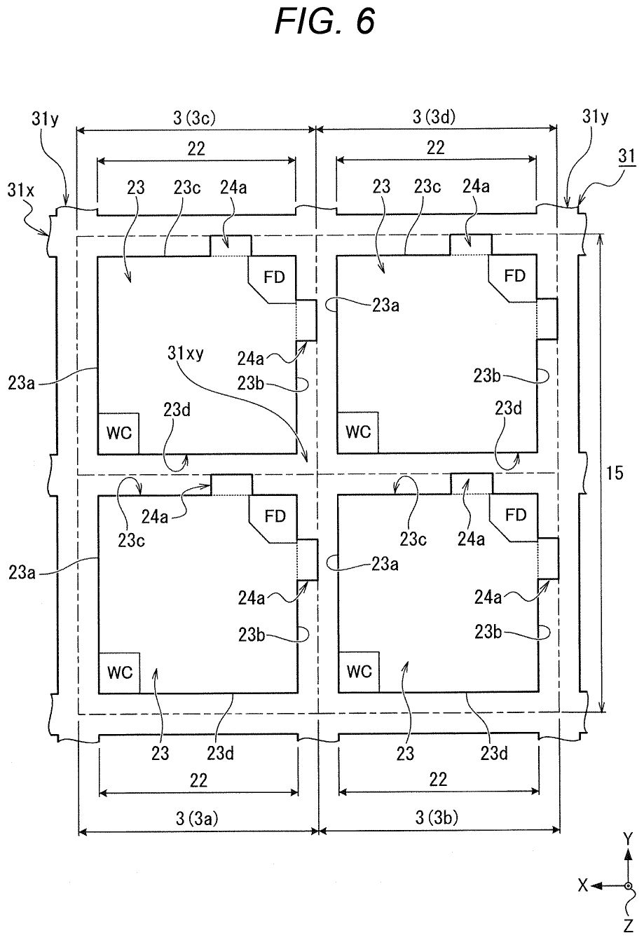

As illustrated in FIGS. 4 and 6, each photoelectric conversion region 22 is surrounded by the isolation region 31 in plan view, and has a rectangular planar shape. Specifically, the photoelectric conversion region 22 is surrounded by two first portions 31x extending in the X direction and separated in the Y direction and two second portions 31y extending in the Y direction and separated in the X direction. The photoelectric conversion region 22 is then partitioned by the first portions 31x and the second portions 31y, and isolated from the other photoelectric conversion regions 22.

As illustrated in FIGS. 4 to 6, each photoelectric conversion region 22 includes a main body 23 provided with the photoelectric conversion unit 27 and the n-type floating diffusion region FD described above, and protrusions 24a protruding from the main body 23 toward an isolation region 31 side in plan view.

### Main Body

As illustrated in FIGS. 4 and 6, the main body 23 has a rectangular planar shape having four sides 23a, 23b, 23c, and 23d. Of the four sides 23a, 23b, 23c, and 23d, the two sides 23a and 23b extend in the Y direction and are located on opposite sides in the X direction. The two remaining sides 23c and 23d extend in the X direction and are located on opposite sides in the Y direction.

As illustrated in FIG. 5, the main body 23 includes the photoelectric conversion unit 27, the transfer transistor TR, and the n-type floating diffusion region FD. The main body 23 further includes a p-type well region 25, an n-type semiconductor region 26, an n-type relay region RA, and a p-type power supply contact region WC.

(p-Type Well Region, n-Type Semiconductor Region, and n-Type Relay Region)

As illustrated in FIG. 5, the p-type well region 25 is provided over a wide range over the first surface S1 side and the second surface S2 side of the semiconductor layer 21 in the main body 23 of the photoelectric conversion region 22. The p-type well region 25 includes a p-type semiconductor region.

As illustrated in FIG. 5, the n-type semiconductor region 26 is provided in the p-type well region 25 in the main body 23 of the photoelectric conversion region 22.

That is, in the n-type semiconductor region 26, the entirety of an upper surface, a lower surface, and four side surfaces are surrounded by the p-type well region 25. The n-type semiconductor region 26 is separated from the first surface S1 and the second surface S2 of the semiconductor layer 21 and the isolation region 31.

As illustrated in FIG. 5, the n-type relay region RA is provided in contact with the n-type semiconductor region 26 between the first surface S1 of the semiconductor layer 21 and the n-type semiconductor region 26 in the main body 23 of the photoelectric conversion region 22. The n-type relay region RA includes an n-type semiconductor region having an impurity concentration higher than that of the n-type semiconductor region 26.

Note that, in the first embodiment, the n-type semiconductor region 26 and the n-type relay region RA are described as separate components, but the n-type relay region RA can also be regarded as a part of the n-type semiconductor region 26.

### (Photoelectric Conversion Unit)

Each photoelectric conversion unit 27 illustrated in FIG. 5 includes the p-type well region 25, the n-type semiconductor region 26, and the n-type relay region RA in the main body 23 of the photoelectric conversion region 22. The photoelectric conversion unit 27 is then configured as a pn junction photodiode (PD) achieved by a pn junction between the p-type well region 25, the n-type semiconductor region 26, and the n-type relay region RA.

The photoelectric conversion unit 27 performs photoelectric conversion on light incident on the n-type semiconductor region 26 from the second surface S2 side of the semiconductor layer 21 into signal charge in the n-type semiconductor region 26, and temporarily holds (accumulates) the signal charge obtained as a result of the photoelectric conversion in the pn junction between the p-type well region 25, the n-type semiconductor region 26, and the n-type relay region RA.

(n-Type Floating Diffusion Region)

As illustrated in FIG. 4, each n-type floating diffusion region FD is provided in a corner sandwiched between the side 23b and the side 23c of the main body 23 in plan view in the main body 23 of the photoelectric conversion region 22. As illustrated in FIG. 5, the n-type floating diffusion region FD is provided in the p-type well region 25 on the first surface S1 side of the semiconductor layer 21. The n-type floating diffusion region FD overlaps the n-type semiconductor region 26 in plan view, and is separated from the n-type semiconductor region 26 in the thickness direction (Z direction) of the semiconductor layer 21. That is, the p-type well region 25 is provided between the n-type floating diffusion region FD and the n-type semiconductor region 26. The n-type floating diffusion region FD includes an n-type semiconductor region having an impurity concentration higher than that of the n-type semiconductor region 26.

(p-Type Power Supply Contact Region)

As illustrated in FIG. 4, each p-type power supply contact region WC is provided in a corner sandwiched between the side 23a and the side 23d of the main body 23 in plan view in the main body 23 of the photoelectric conversion region 22. That is, the p-type power supply contact region WC is provided in a corner located diagonally to the corner where the n-type floating diffusion region FD is provided among four corners of the main body 23 in plan view. As illustrated in FIG. 5, the p-type power supply contact region WC is provided in the p-type well region 25 on the first surface S1 side of the semiconductor layer 21. The p-type power supply contact region WC overlaps the n-type semiconductor region 26 in plan view and is separated from the n-type semiconductor region 26. The p-type power supply contact region WC includes a p-type semiconductor region and is electrically connected to the n-type well region 25.

### (Transfer Transistor)

As illustrated in FIG. 5, each transfer transistor TR is provided on the first surface S1 side of the semiconductor layer 21 in the main body 23 of the photoelectric conversion region 22. The transfer transistor TR includes a gate electrode 43 provided on the first surface S1 side of the semiconductor layer 21 and a gate insulating film 42 provided between the gate electrode 43 and the semiconductor layer 21. Furthermore, the transfer transistor TR further includes the n-type semiconductor region 26 and the n-type relay region RA that function as source regions, the n-type floating diffusion region FD that functions as a drain region, and the p-type well region 25 that functions as a channel formation region. Although not limited to this, the transfer transistor TR is of, for example, an n-channel conductivity type. In addition, the transfer transistor TR is of a planar type in which the gate electrode 43 is provided outside the first surface S1 of the semiconductor layer 21 via the gate insulating film 42.

As illustrated in FIG. 4, the transfer transistor TR is provided closer to the corner where the n-type floating diffusion region FD is provided among the four corners of the main body 23 in plan view. The gate electrode 43 of the transfer transistor TR is provided closer to the n-type floating diffusion region FD than to the p-type power supply contact region WC.

Referring to FIG. 5, when the transfer transistor TR is turned on by application of a gate voltage to the gate electrode 43, a charge transfer path (channel) electrically connecting the n-type relay region RA of the photoelectric conversion unit 27 and the n-type floating diffusion region FD is formed in the p-type well region 25. Signal charge obtained as a result of photoelectric conversion in the n-type semiconductor region 26 of the photoelectric conversion unit 27 is transferred from the n-type relay region RA (photoelectric conversion unit 27) to the n-type floating diffusion region FD through the charge transfer path (channel).

### Protrusion

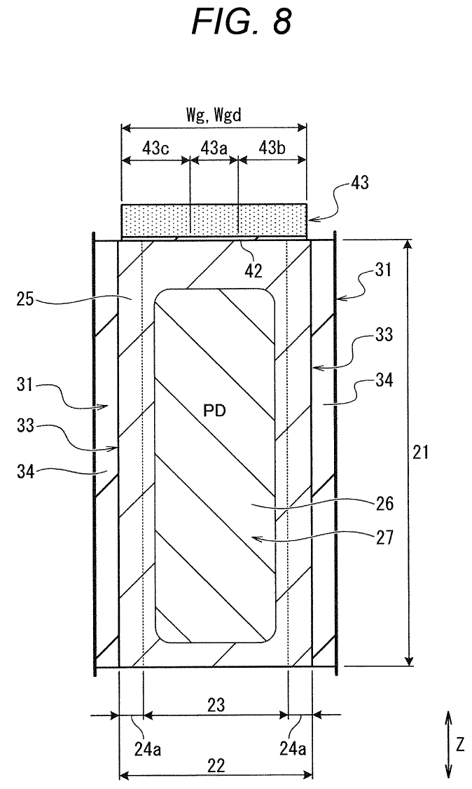

As illustrated in FIGS. 4 and 6, the protrusions 24a are provided on sides of the main body 23 in plan view. In the first embodiment, a protrusion 24a is provided on each of the two sides 23b and 23c of the main body 23. As illustrated in FIG. 8, the protrusions 24a extend along the thickness direction (Z direction) of the semiconductor layer 21 and are provided over the first surface S1 side and the second surface S2 side of the semiconductor layer 21. Although described in detail later, as illustrated in FIG. 8, the protrusions 24a are provided at positions overlapping the gate electrode 43 in plan view.

### Relationship between Gate Electrode and Protrusions

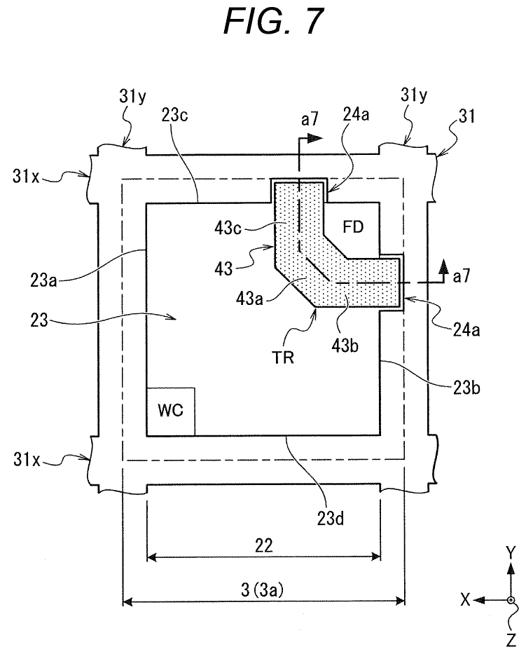

As illustrated in FIGS. 7 and 8, the gate electrode 43 of each transfer transistor TR is provided over the main body 23 and the protrusions 24 of the photoelectric conversion region 22 on the first surface S1 side of the semiconductor layer 21. That is, the transfer transistor TR includes the gate electrode 43 provided over the main body 23 and the protrusions 24 of the photoelectric conversion region 22.

As illustrated in FIGS. 7 and 8, a protrusion 24 is provided on each of the two sides 23b and 23c of the main body 23 in plan view. One end and another end of the gate electrode 43 of the transfer transistor TR in a gate width direction Wgd overlap the two protrusions 24. In the first embodiment, a protrusion 24a is provided on each of two sides 23b and 23c extending in different directions among the four sides 23a, 23b, 23c, and 23d of the main body 23 in plan view. One end and another end of the gate electrode 43 of the transfer transistor TR in a gate width direction Wgd overlap the two protrusions 24a. The main body 23 and the protrusions 24a of the photoelectric conversion region 22 are arranged along the gate width direction Wgd of the gate electrode 43.

As illustrated in FIGS. 7 and 8, the gate electrode 43 includes an inclined portion 43a that is separated from a corner sandwiched between the sides 23b and 23c of the main body 23 in plan view and that extends obliquely with respect to the side 23b and the side 23c of the main body 23, a first straight portion 43b that extends from one end of the inclined portion 43a toward the protrusion 24a on the side 23b of the main body 23, and a second straight portion 43c that extends from another end of the inclined portion 43a opposite to the one end toward the protrusion 24a on the side 23c of the main body 23. That is, in the gate electrode 43, each of the first straight portion 43b and the second straight portion 43c extends over the main body 23 and the protrusion 24a of the photoelectric conversion region 22. The gate electrode 43 has a substantially L-shaped planar shape. The gate electrode 43 of the first embodiment has a bent portion between the one end and the another end in plan view.

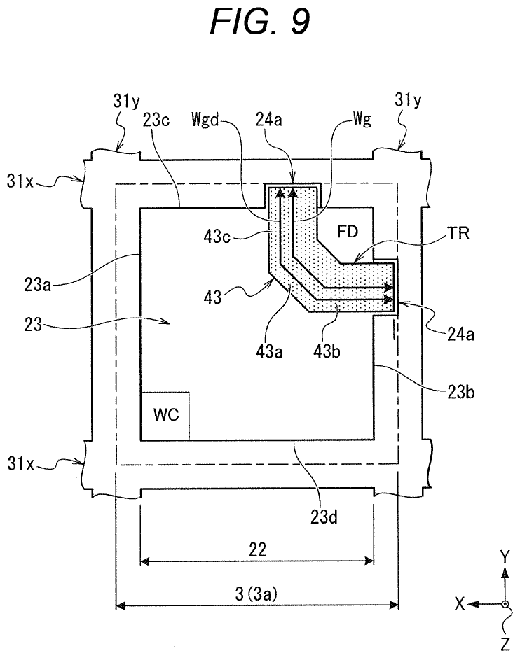

Here, referring to FIG. 9, a lateral direction of the gate electrode 43 is a gate length direction, and a longitudinal direction of the gate electrode 43 is the gate width direction Wgd. In the first embodiment, since the planar shape of the gate electrode 43 is substantially L-shaped including the inclined portion 43a, the first straight portion 43b, and the second straight portion 43c, the gate width direction Wgd is also a direction along the substantially L-shape of the gate electrode 43. A gate width Wg of the gate electrode 43 includes a length of each of the inclined portion 43a, the first straight portion 43b, and the second straight portion 43c in the gate width direction Wgd in an overlapping region where the gate electrode 43 overlaps the semiconductor layer 21 in plan view. In the first embodiment, since the entirety of the gate electrode 43 overlaps the semiconductor layer 21, the length from the one end to the another end of the gate electrode 43 is the gate width Wg.

Note that, as illustrated in FIG. 8, in the first embodiment, the n-type well region 25 is also provided in the protrusions 24a, but n-type semiconductor regions 26 are not provided in the protrusions 24a.

### Pixel Transistors

As illustrated in FIG. 4, each photoelectric conversion region 22 further includes, but is not limited to, a pixel transistor Q included in the pixel circuit 16 of FIG. 3. In the first embodiment, for example, as illustrated in FIG. 4, among the four pixels 3 (3a, 3b, 3c, and 3d) included in one pixel block 15, the photoelectric conversion region 22 of the pixel 3a further includes the amplification transistor AMP as the pixel transistor Q, the photoelectric conversion region 22 of the pixel 3b further includes the selection transistor SEL as the pixel transistor Q, the photoelectric conversion region 22 of the pixel 3c further includes the reset transistor RST as the pixel transistor Q, and the photoelectric conversion region 22 of the pixel 3d further includes the switching transistor FDG.

Note that, in the first embodiment, a case where the pixel transistors Q included in the pixel circuit 16 are provided in the photoelectric conversion regions 22 has been described, but the pixel transistors Q may be provided in another semiconductor layer stacked on the semiconductor layer 21, instead.

### Method for Manufacturing Solid-state Imaging Device

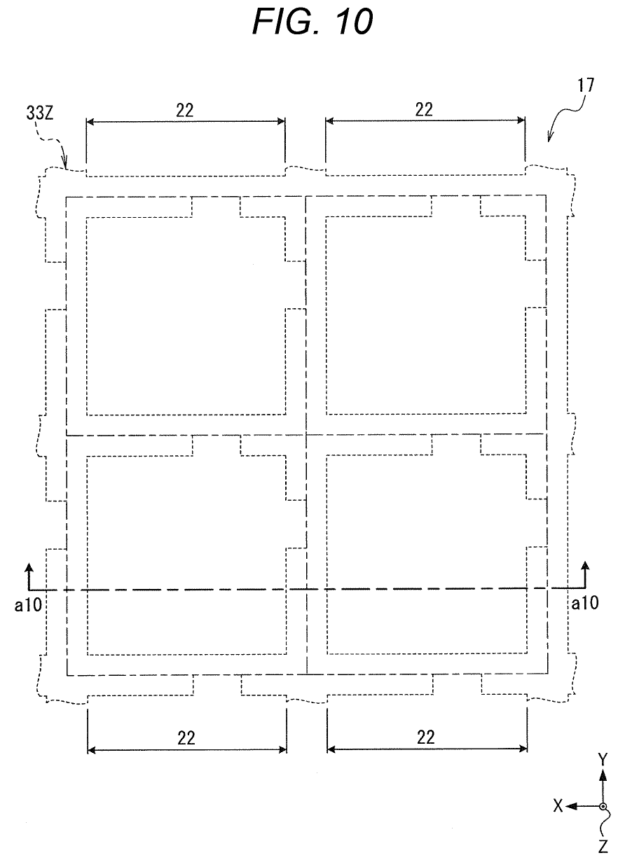

A method for manufacturing the solid-state imaging device 1A according to the first embodiment of the present technology will be described with reference to FIGS. 10 to 16.

In the first embodiment, manufacturing of the isolation region 31 and the photoelectric conversion regions 22 included in the method for manufacturing the solid-state imaging device 1A will be specifically described.

Furthermore, in FIGS. 10 to 16, a pixel block formation region 17 corresponding to the one pixel block 15 illustrated in FIGS. 4 and 5 is illustrated. Therefore, the pixel block formation region 17 includes four photoelectric conversion regions 22 each surrounded by a dug portion formation region 33Z.

First, as illustrated in FIG. 10 (plan view) and 11 (longitudinal sectional view), the p-type well region 25 and the n-type semiconductor regions 26 are formed in the semiconductor layer 21. The p-type well region 25 is formed over an entire region including the photoelectric conversion regions 22 and the dug portion formation regions 33Z of the semiconductor layer 21. The n-type semiconductor region 26 is selectively formed for each photoelectric conversion region 22. FIG. 10 illustrates four photoelectric conversion regions 22 that are not yet partitioned in the one pixel block formation region 17. The four photoelectric conversion regions 22 have a 2×2 arrangement in which two photoelectric conversion regions are arranged in each of the X direction and the Y direction. Each of the p-type well region 25 and the n-type semiconductor regions 26 can be formed by a known photolithography technique and an impurity ion implantation method.

In this step, the n-type semiconductor regions 26 are provided in the p-type well region 25, and an upper surface, a lower surface, and four side surfaces (six surfaces) are surrounded by the p-type well region 25.

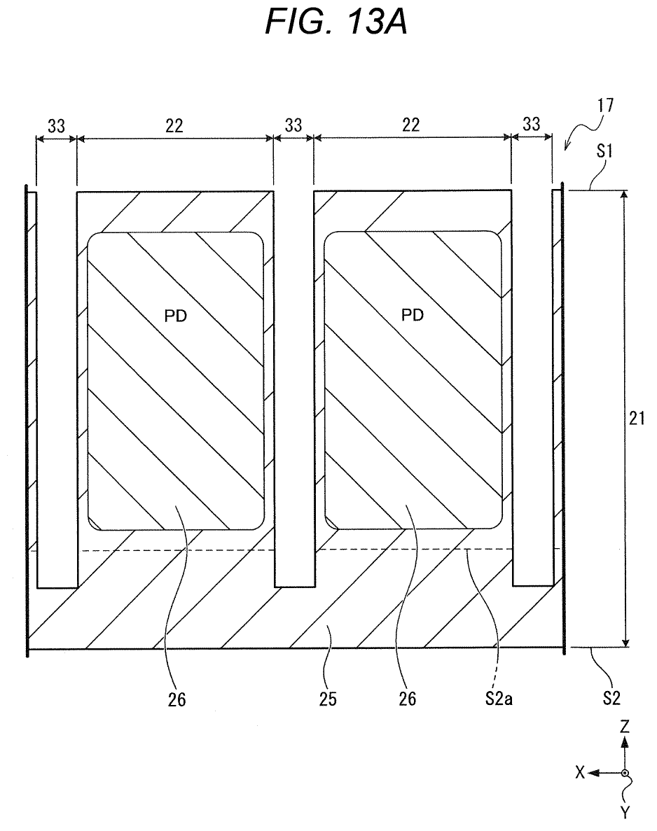

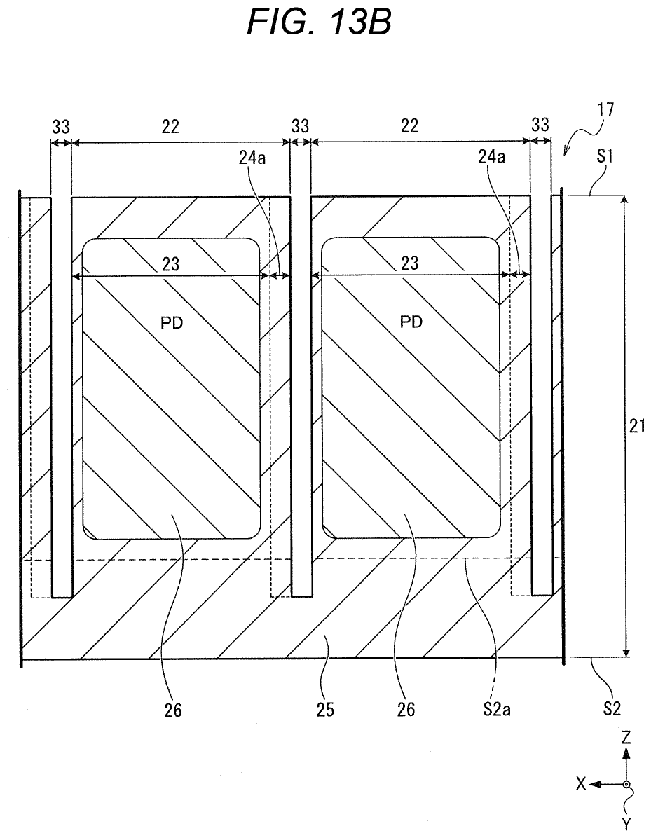

Furthermore, in this step each photoelectric conversion region 22 is not yet partitioned, and is virtually surrounded by the dug portion formation region 33Z in which the dug portion 33 (see FIGS. 13A and 13B) is formed in a subsequent step. The dug portion formation region 33Z is not physically formed, but is set as a lattice-shaped planar pattern surrounding each photoelectric conversion region 22.

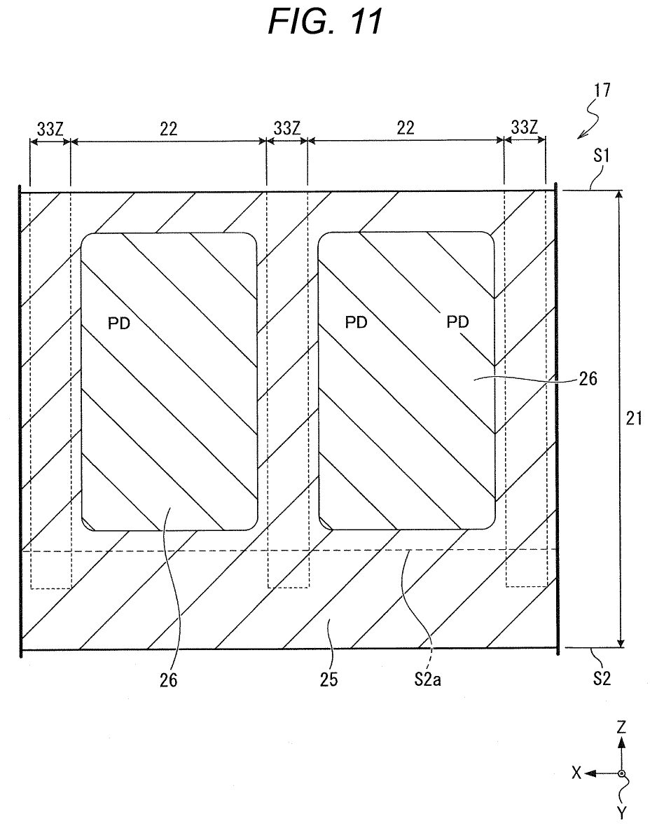

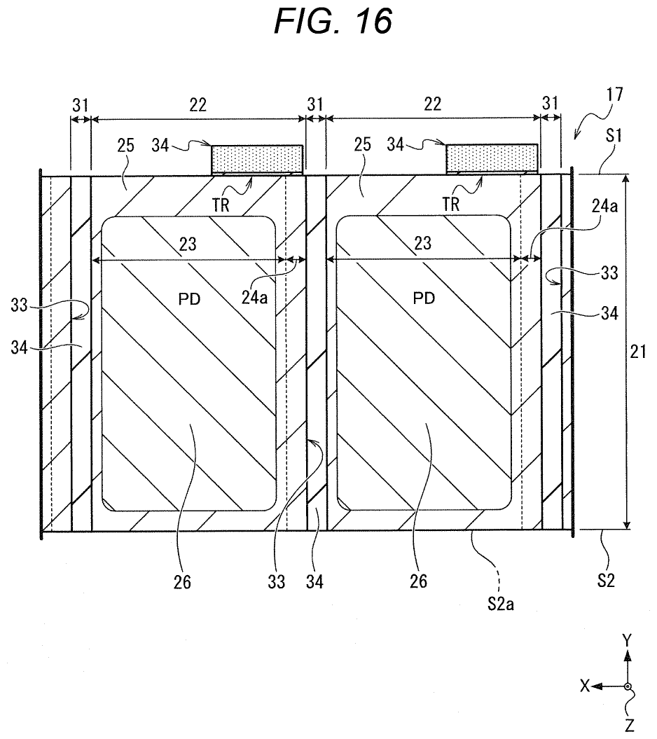

Here, in the manufacture of the solid-state imaging device 1A of the first embodiment, a thinning step (see FIG. 16) of thinning the thickness of the semiconductor layer 21 in the Z direction is performed. In the thinning process, the semiconductor layer 21 is thinned to a thinning line S2a illustrated in FIG. 11.

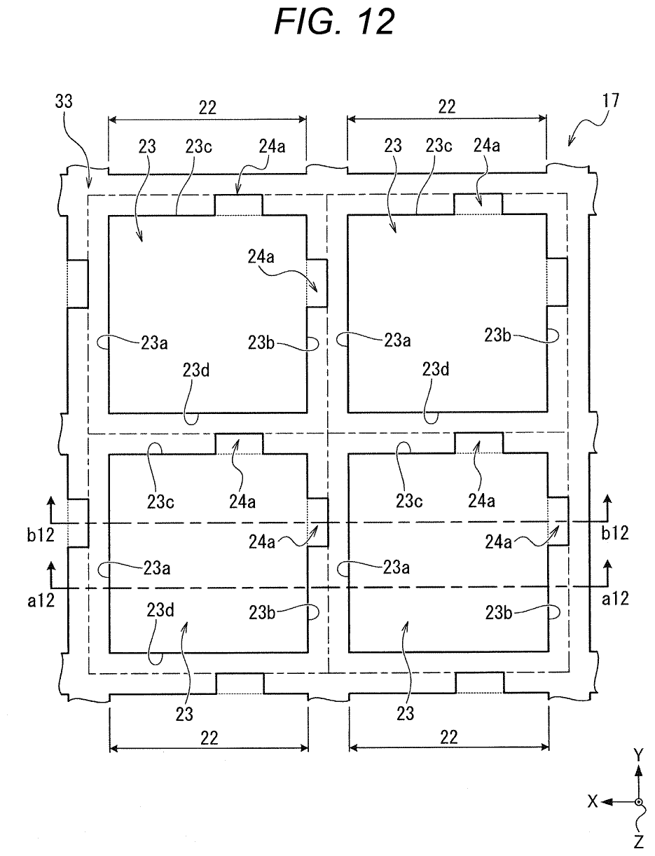

Next, each dug portion formation region 33Z is selectively etched to form the dug portion 33 surrounding the photoelectric conversion region 22 and extending from the first surface S1 toward the second surface S2 of the semiconductor layer 21 as illustrated in FIG. 12 (plan view), 13A (longitudinal sectional view), and 13B (longitudinal sectional view).

The dug portion 33 is formed such that the photoelectric conversion region 22 has a shape including the main body 23 and the protrusion 24a protruding from the main body 23 toward the dug portion 33. The dug portion 33 is formed in a lattice-shaped planar pattern surrounding each photoelectric conversion region 22. The dug portion 33 is formed deeper than the thinning line S2a of the semiconductor layer 21 used in the subsequent thinning step. The dug portion 33 can be formed, for example, by selectively etching the dug portion formation region 33Z of the semiconductor layer 21 using a known photolithography technique and an isotropic dry etching technique.

In this step, the photoelectric conversion regions 22 are partitioned and isolated by the dug portions 33, and are formed in a shape including the main body 23 and the protrusions 24a. The main body 23 is formed in a rectangular planar shape having the four sides 23a, 23b, 23c, and 23d. The protrusion 24a is provided on each of the two sides 23b and 23c extending in different directions among the four sides 23a, 23b, 23c, and 23d of the main body 23 in plan view. In addition, the protrusion 24a is formed at a position overlapping the gate electrode 43 to be formed in a later step. The protrusion 24a extends from the first surface S1 toward the second surface S2 of the semiconductor layer 21.

Next, after the dug portions 33 are formed in the semiconductor layer 21 to partition the photoelectric conversion regions 22, a cleaning step (not illustrated) is performed.

In the cleaning step, since each photoelectric conversion region 22 includes the main body 23 and the protrusions 24a protruding from the main body 23 toward the dug portions 33, it is possible to improve resistance stress that makes bending (falling) of the photoelectric conversion regions 22 hardly occur due to capillary force (surface tension) caused by evaporation of a cleaning liquid.

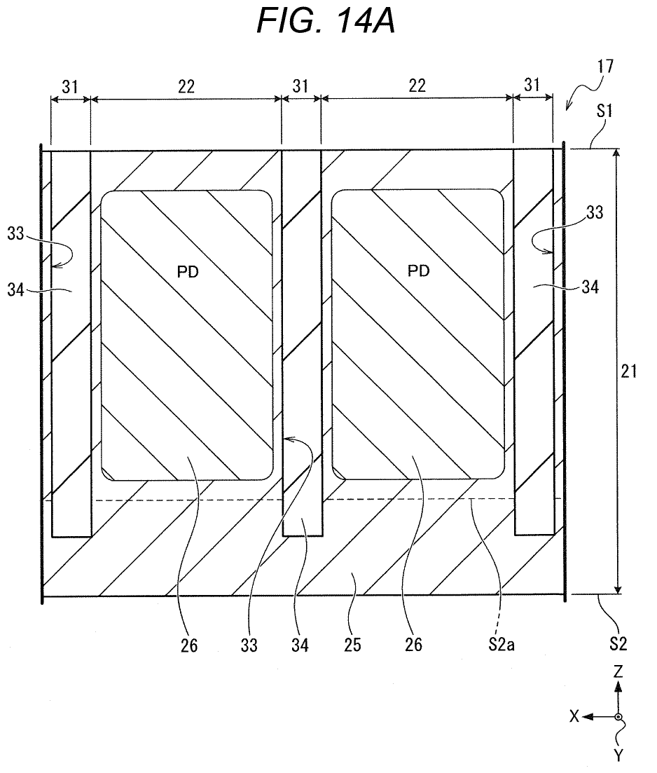

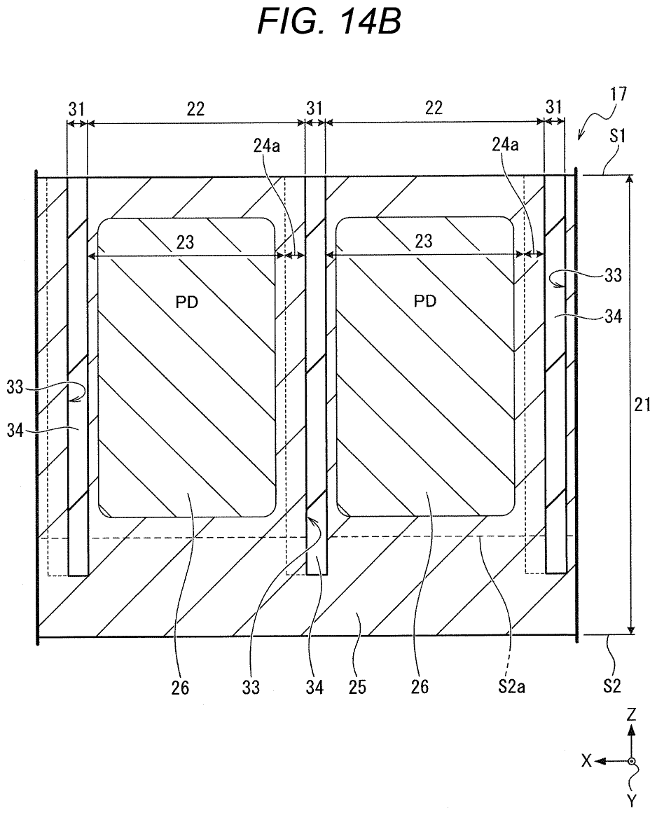

Next, after the cleaning step is performed, as illustrated in FIGS. 14A and 14B, the isolation insulating films 34 are selectively formed inside the dug portions 33. The isolation insulating films 34 are formed in such a way as to embed the inside of the dug portions 33.

The isolation insulating films 34 inside the dug portions 33 can be formed, for example, by forming an isolation insulating film 34 all over the first surface S1 of the semiconductor layer 21 including the inside of the dug portions 33, and then selectively removing the isolation insulating film 34 on the first surface S1 of the semiconductor layer 21 by a CMP method, an etchback method, or the like. As the isolation insulating film 34, for example, a silicon oxide film may be used.

In this step, the isolation region 31 including the dug portions 33 and the isolation insulating films 34 provided inside the dug portions 33 is formed. The photoelectric conversion regions 22 are then partitioned by the isolation region 31, and electrically and optically isolated from other adjacent photoelectric conversion regions 22.

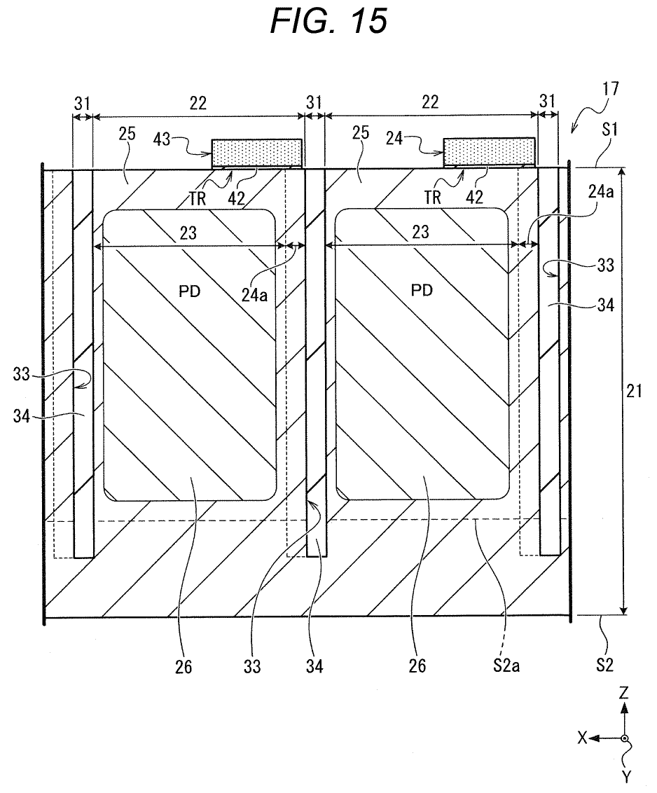

Next, in each photoelectric conversion region 22, as illustrated in FIG. 15, the transfer transistors TR including the gate electrodes 43 are formed, and although not illustrated, the n-type relay regions RA, the n-type floating diffusion regions FD, the p-type power supply contact regions WC, the pixel transistors Q, and the like are formed. The gate electrodes 43, the n-type relay regions RA, the n-type floating diffusion regions FD, the p-type power supply contact regions WC, the pixel transistors Q, and the like are formed at positions illustrated in FIGS. 4 and 5.

In this step, as illustrated in FIG. 15, the gate electrodes 43 are formed outside the first surface S1 of the semiconductor layer 21 with the gate insulating films 42 interposed therebetween. The gate electrodes 43 are then formed over the main bodies 23 and the protrusions 24a of the photoelectric conversion regions 22 in plan view.

Next, although not illustrated, a multilayer wiring layer is formed on the first surface S1 side of the semiconductor layer 21, and then, as illustrated in FIG. 16, the thinning step of cutting the second surface S2 side of the semiconductor layer 21 to the thinning line S2a by, for example, a CMP method to thin the thickness of the semiconductor layer 21 is performed.

In this step, the isolation region 31 extending from the first surface S1 side of the semiconductor layer 21 along the thickness direction (Z direction) of the semiconductor layer 21 and reaching the second surface S2 of the semiconductor layer 21 is formed, and the photoelectric conversion regions 22 partitioned by the isolation region 31 and including the main bodies 23 and the protrusions 24a are formed.

Thereafter, the planarization film 51, the optical filters 53, and the microlenses 54 are formed in this order on the second surface S2 side of the semiconductor layer 21, and the state illustrated in FIGS. 4A to 5B is achieved.

### MAIN EFFECTS OF FIRST EMBODIMENT

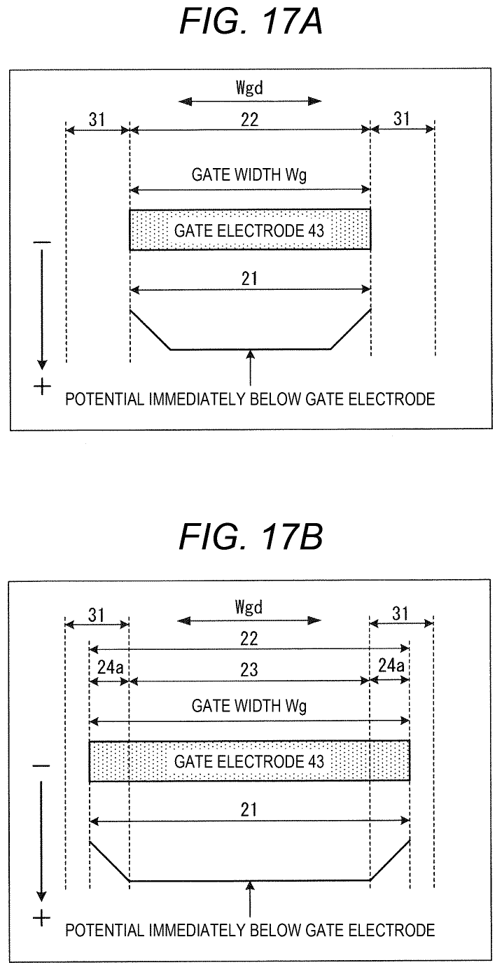

Next, main effects of the first embodiment will be described with reference to FIGS. 17A and 17B.

FIG. 17A is a diagram illustrating an example of a potential in the semiconductor layer 21 immediately below the gate electrode 43 in a conventional technique in which the gate electrode 43 of the transfer transistor TR is provided in a photoelectric conversion region not including protrusions.

FIG. 17B is a diagram illustrating an example of a potential in the semiconductor layer 21 immediately below the gate electrode 43 in the first embodiment of the present technology in which the gate electrode 43 of the transfer transistor TR is provided over the main body 23 and the protrusions 24a of the photoelectric conversion region 22.

Note that, in FIG. 17A of the conventional technique, the same portions as those of the first embodiment of the present technology are denoted by similar reference numerals.

As illustrated in FIG. 17A, when a downward direction indicates a positive potential, the potential in the semiconductor layer 21 immediately below the gate electrode 43 (the semiconductor layer 21 overlapping the gate electrode 43 in plan view) is lower toward the ends of the gate electrode 43 in the gate width direction Wgd. Since there is no bias from the outside of the gate electrode 43 at the ends of the gate electrode 43 in the gate width direction Wgd as compared with the center of the gate electrode 43 in the gate width direction Wgd, the potential becomes low. Therefore, current driving force, that is, transconductance (gm), deteriorates at the ends of the gate electrode 43 in the gate width direction Wgd.

On the other hand, since the gate width Wg of the gate electrode 43 is shortened due to the miniaturization of the transfer transistor TR accompanying the reduction of the pixel size, the transconductance of the transfer transistor TR is deteriorated.

On the other hand, as illustrated in FIG. 17B, the photoelectric conversion region 22 of the first embodiment includes the main body 23 and the protrusions 24a protruding from the main body 23 toward the isolation region 31. The transfer transistor TR of the first embodiment includes the gate electrode 43 provided over the main body 23 and the protrusions 24a of the photoelectric conversion region 22 on the first surface S1 side of the semiconductor layer 21. That is, in the first embodiment, the gate electrode 43 extends from the main body 23 corresponding to the conventional photoelectric conversion region to the protrusions 24a in a planar direction of the first surface S1 of the semiconductor layer 21.

Therefore, the gate width Wg of the gate electrode 43 becomes longer and the potential to be effectively used can be increased, and the transconductance (gm) of the transfer transistor TR can be improved, that is, the transconductance (gm) can be enhanced, as compared with the conventional technique illustrated in FIG. 17A.

Next, advantages of the first embodiment in the manufacturing process will be described with reference to FIGS. 12, 13A, and 13B in comparison with the case of the conventional photoelectric conversion region.

In the manufacturing process of the first embodiment, as illustrated in FIGS. 12, 13A, and 13B, after the dug portions 33 are formed to partition the photoelectric conversion regions 22, the cleaning step is performed.

In the cleaning step, since the conventional photoelectric conversion regions have a simple rectangular parallelepiped shape, the photoelectric conversion regions might bend in such a way as to fall toward the dug portions 33 due to capillary force (surface tension) caused by evaporation of the cleaning liquid, as described with reference to FIGS. 12, 13A, and 13B. Due to the bending, a width narrowing phenomenon occurs in which the width of the dug portions 33 on an open end side (the first surface S1 side of the semiconductor layer 21) between two photoelectric conversion regions adjacent in plan view becomes narrower than a design value. When the width narrowing phenomenon occurs, it is difficult to embed the films inside the dug portions 33, which causes a decrease in yield.

In recent years, in a device that handles infrared light, in order to improve quantum efficiency QE, studies have been made to increase thickness of a semiconductor layer 21 in the Z direction and to extend an optical path length in the semiconductor layer 21 in a photoelectric conversion region. However, as the thickness of the semiconductor layer 21 increases, an aspect ratio of the dug portions 33 increases (becomes higher), and the photoelectric conversion region falls toward the dug portions 33 side remarkably.

On the other hand, each photoelectric conversion region 22 of the first embodiment includes the protrusions 24a protruding from the main body 23 corresponding to the conventional photoelectric conversion region toward the dug portions 33. Therefore, in the cleaning step after the dug portions 33 are formed in the semiconductor layer 21 to partition the photoelectric conversion regions 22, it is possible to improve the resistance stress that makes bending (falling) of the photoelectric conversion regions 22 hardly occur due to the capillary force (surface tension) caused by the evaporation of the cleaning liquid, and it is easy to embed the films inside the dug portions 33.

Therefore, with the solid-state imaging device 1A according to the first embodiment, it is possible to improve the manufacturing yield as compared with the case of the conventional simple rectangular parallelepiped photoelectric conversion regions.

Note that, as a method of providing the photoelectric conversion regions 22 with the protrusions 24a, there are a method of reducing planar size of the photoelectric conversion regions 22 except for a part thereof and a method of narrowing width of a part of the isolation region 31. In either method, the protrusions 24a have a shape protruding from the main body 23 toward the isolation region 31 in plan view.

### MODIFICATIONS OF FIRST EMBODIMENT

### Modification 1-1

In the first embodiment described above, as illustrated in FIG. 8, the case where each n-type semiconductor region 26 is selectively provided in the main body 23 of the photoelectric conversion region 22 has been described, but the present technology is not limited to the n-type semiconductor region 26 illustrated in FIG. 8.

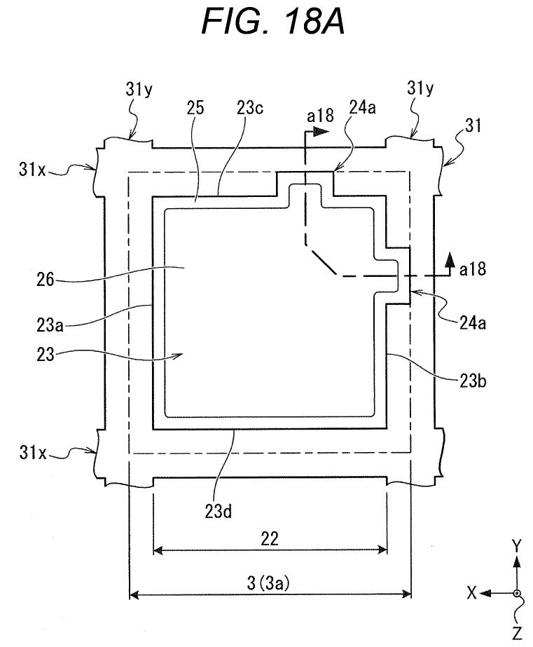

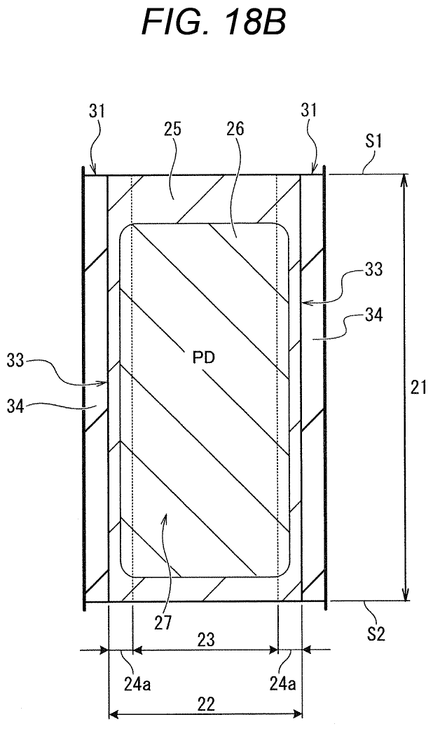

For example, as illustrated in FIGS. 18A and 18B, each n-type semiconductor region 26 may be provided over the main body 23 and the protrusions 24a of the photoelectric conversion region 22. In other words, each n-type semiconductor region 26 may be configured to protrude from the main body 23 to the protrusions 24a. In this case, since volume of the n-type semiconductor region 26 increases, a saturation signal amount Qs can be further improved.

Note that, in FIGS. 18A and 18B, the transfer transistor TR, the n-type floating diffusion region FD, the power supply contact region WC, the planarization film 51, the optical filter 53, the microlens 54, and the like are not illustrated.

### Modification 1-2

Furthermore, in the first embodiment described above, as illustrated in FIG. 6, the case where the protrusions 24a overlapping the gate electrodes 43 of the transfer transistors TR are provided as the protrusions protruding from the main bodies 23 of the photoelectric conversion regions 22 toward the isolation region 31 has been described, but the protrusions are not limited to the protrusions 24a overlapping the gate electrodes 43 of the transfer transistors TR.

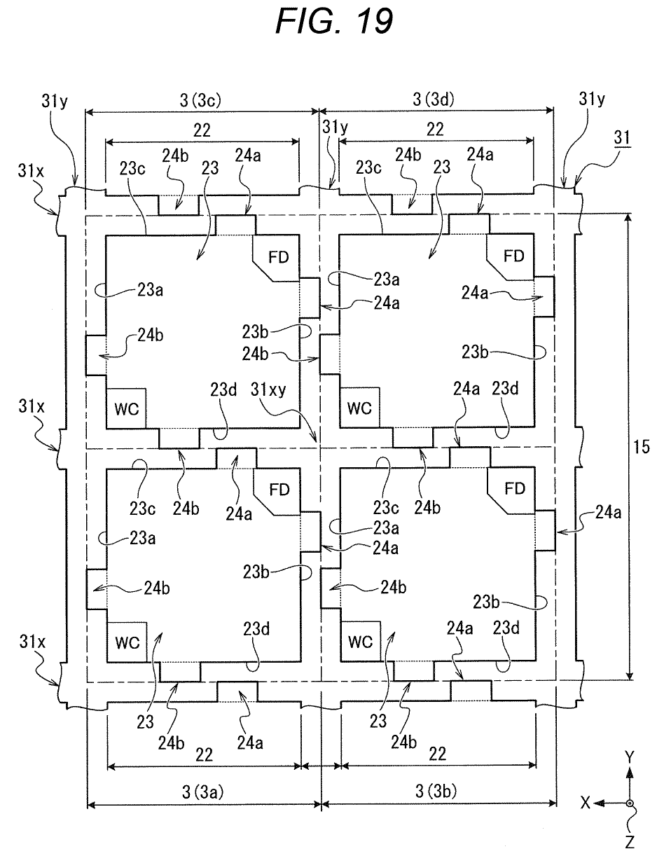

For example, as illustrated in FIG. 19, protrusions 24b protruding from the main body 23 of each photoelectric conversion region 22 toward the isolation region 31 may be provided separately from the protrusions 24a overlapping with the gate electrode 43 of each transfer transistor TR. Among the four sides 23a, 23b, 23c, and 23d of the main body 23 of the photoelectric conversion region 22 in plan view, the protrusions 24b are preferably arranged on sides other than the sides on which the protrusions 24a overlapping the gate electrode 43 in plan view are arranged. In the first embodiment described above, since the protrusions 24a are provided on the side 23b and the side 23c of the main body 23, the protrusions 24b are preferably provided on the side 23a and the side 24d of the main body 23.

In addition, as illustrated in FIG. 19, it is preferable that the positions of the protrusions 24b are shifted in such a way as not to be adjacent to each other in the X direction and the Y direction in two photoelectric conversion regions 22 adjacent to each other in plan view.

In addition, the protrusions 24b are preferably provided at positions not adjacent to the protrusions 24a in plan view in two photoelectric conversion regions 22 adjacent to each other in plan view.

### Modifications 1-3 and 1-4

Furthermore, in the first embodiment described above, the planar shape of the gate electrode 43 of the transfer transistor TR is substantially L-shaped as illustrated in FIG. 7, but the present technology is not limited to the gate electrode 43 having a substantially L-shaped planar shape.

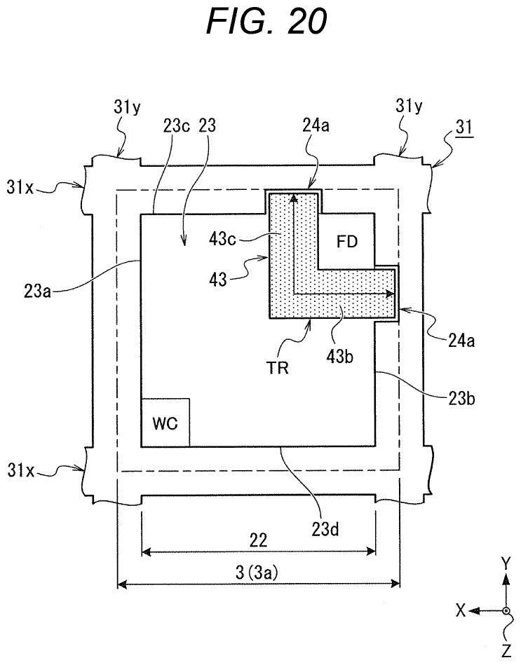

For example, as illustrated in FIG. 20, the present technology can also be applied to a transfer transistor TR having a gate electrode 43 having an L-shaped planar shape. The L-shaped gate electrode 43 includes a first straight portion 43b extending from one end overlapping with the main body 23 of the photoelectric conversion region 22 toward the protrusion 24a on the side 23b of the main body 23 in plan view in the X direction, and a second straight portion 43c extending from the one end of the first straight portion 43b toward the protrusion 24a on the side 23c of the main body 23 in plan view in the Y direction. The gate electrode 43 of Modification 1-3 also has a bent portion between one end and another end in plan view.

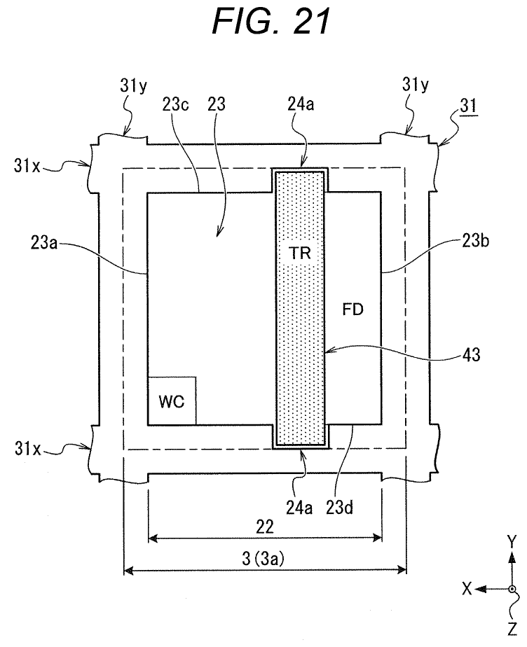

In addition, as illustrated in FIG. 21, the present technology can also be applied to a transfer transistor TR having a gate electrode 43 having an I-shaped planar shape. The I-shaped gate electrode 43 extends such that an intermediate portion overlaps the main body 23 of the photoelectric conversion region 22 and one end and another end located on opposite sides individually overlap the protrusions 24a on two sides located on opposite sides of the main body 23 of the photoelectric conversion region 22. FIG. 21 illustrates the gate electrode 43 extending in the Y direction as an example, but the present technology can also be applied to a case where the gate electrode 43 extends in the X direction.

### Modification 1-5

Furthermore, in the first embodiment described above, the isolation region 31 linearly extending in the thickness direction (Z direction) of the semiconductor layer 21 has been described, but the present technology is not limited to the isolation regions 31 of the first embodiment described above.

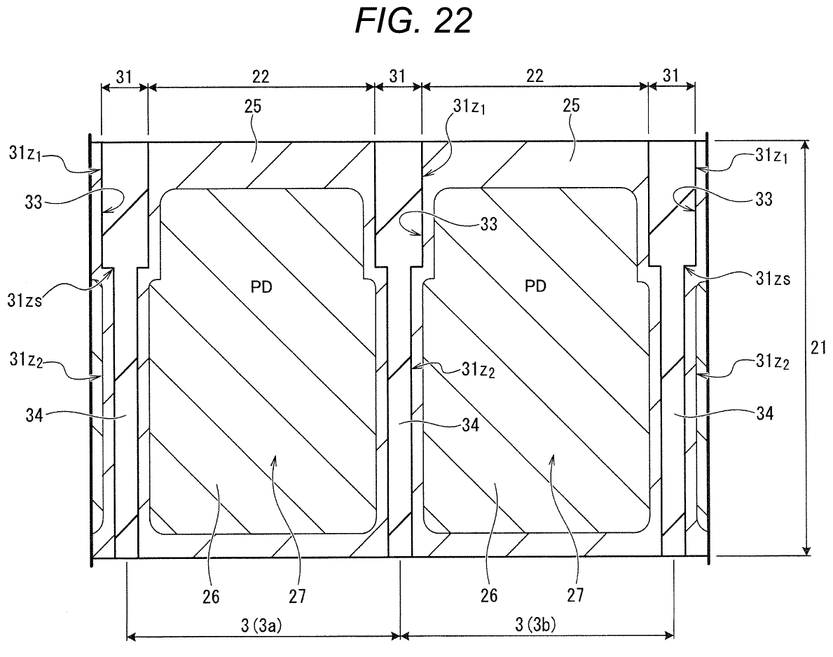

For example, as illustrated in FIG. 22, the isolation region 31 may include a first vertical portion 31z₁ provided on the first surface S1 side of the semiconductor layer 21, a second vertical portion 31z₂ extending from the first vertical portion 31z₁ toward the second surface S2 side of the semiconductor layer 21 and having a width narrower than width of the first vertical portion 31z₁, and a stepped portion 31zs due to a difference between the width of the first vertical portion 31z₁ and the width of the second vertical portion 31z₂ in the thickness direction (Z direction) of the semiconductor layer 21. In Modification 1-5, since volume of the n-type semiconductor regions 26 increases as compared with the above-described first embodiment, the saturation signal amount Qs can be further improved.

Note that FIG. 22 is a longitudinal sectional view illustrating a longitudinal sectional structure at the same position as section line a10-a10 in FIG. 10.

Furthermore, in FIG. 22, the planarization film 51, the optical filters 53, the microlenses 54, and the like are not illustrated.

### SECOND EMBODIMENT

A solid-state imaging device 1B according to a second embodiment of the present technology basically has a similar configuration to that of the above-described first embodiment, and the arrangement of the n-type floating diffusion region FD and the transfer transistor TR of each of the four photoelectric conversion regions 22 (four pixels 3a, 3b, 3c, and 3d) included in one pixel block 15 is different.

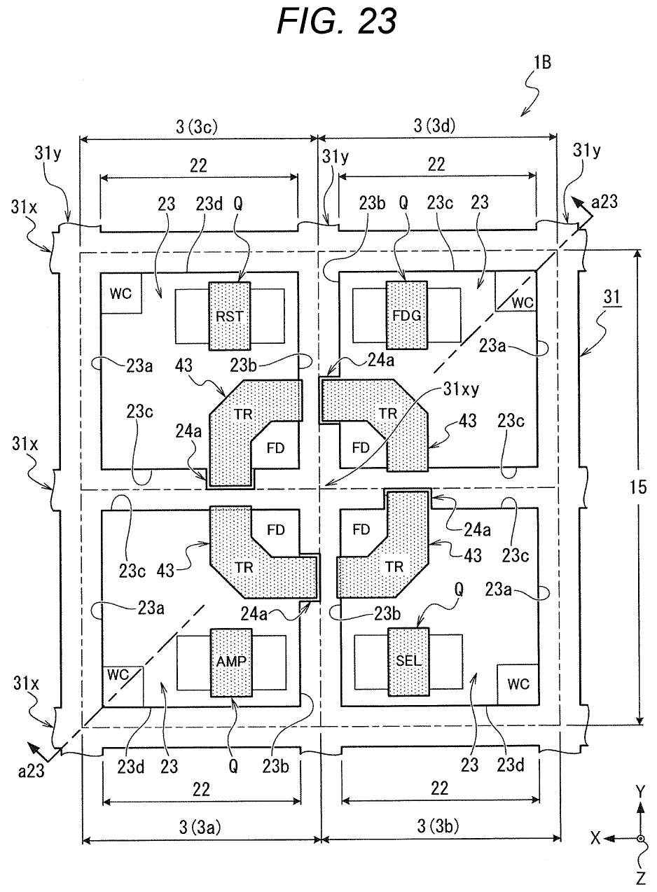

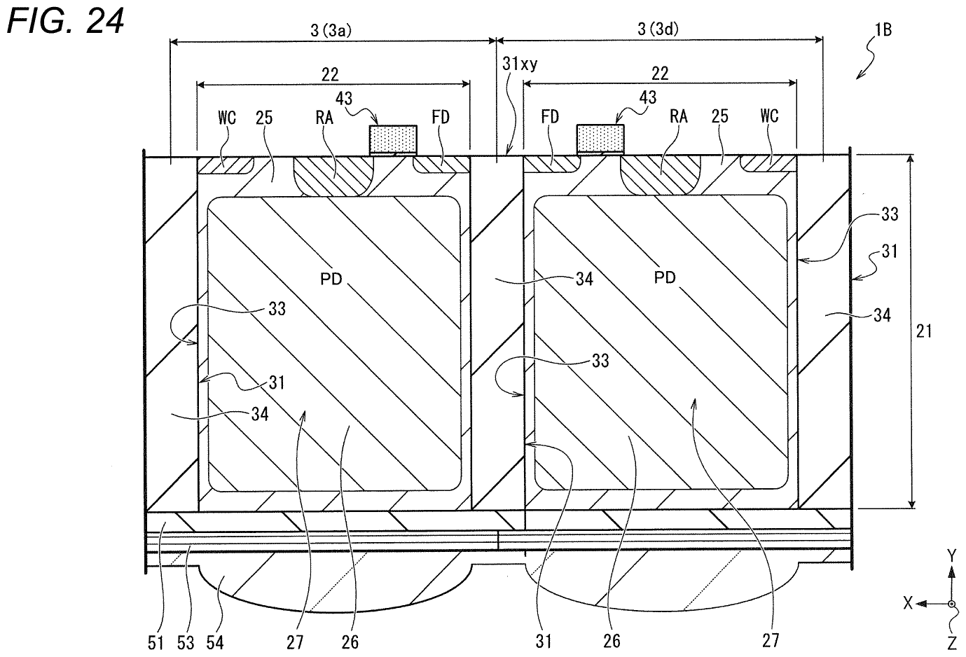

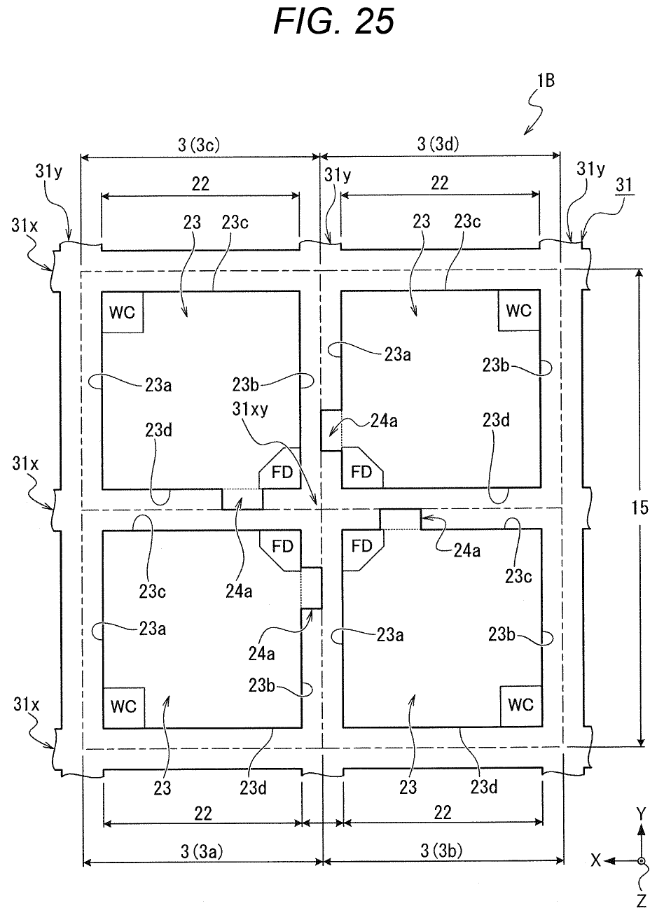

That is, as illustrated in FIG. 23 (plan view), FIG. 24 (a longitudinal sectional view taken along section line a23-a23 in FIG. 23), and FIG. 25 (a plan view in which the gate electrodes of the transfer transistors in FIG. 23 are omitted), the n-type floating diffusion region FD of each of the four photoelectric conversion regions 22 (four pixels 3a, 3b, 3c, and 3d) included in one pixel block 15 of the second embodiment is provided adjacent to an intersection portion 31xy of the isolation region 31 outside the intersection portion 31xy in such a way as to surround the intersection portion 31xy in plan view.

In addition, as illustrated in FIGS. 23 to 25, the transfer transistors RT of the four photoelectric conversion regions 22 (four pixels 3a, 3b, 3c, and 3d) included in one pixel block 15 are provided in such a way as to be biased to an intersection portion 31xy side of the isolation region 31 in plan view. The gate electrode 43 of the transfer transistor TR of each of the four photoelectric conversion regions 22 is provided outside the n-type floating diffusion region FD in such a way as to surround the intersection portion 31xy of the isolation region 31 in plan view.

In the case of the second embodiment, since the gate electrodes 43 of the four photoelectric conversion regions 22 are adjacent to each other in plan view, it is preferable that one of two gate electrodes 43 adjacent to each other in plan view is superimposed on the protrusion 24a of the photoelectric conversion region 22.

The solid-state imaging device 1B according to the second embodiment can also produce effects similar to the effects produced by the solid-state imaging device 1A according to the first embodiment described above.

### THIRD EMBODIMENT

A solid-state imaging device 1C according to a third embodiment of the present technology basically has a similar configuration to that in the first embodiment described above, but is different in terms of the configuration of the transfer transistor.

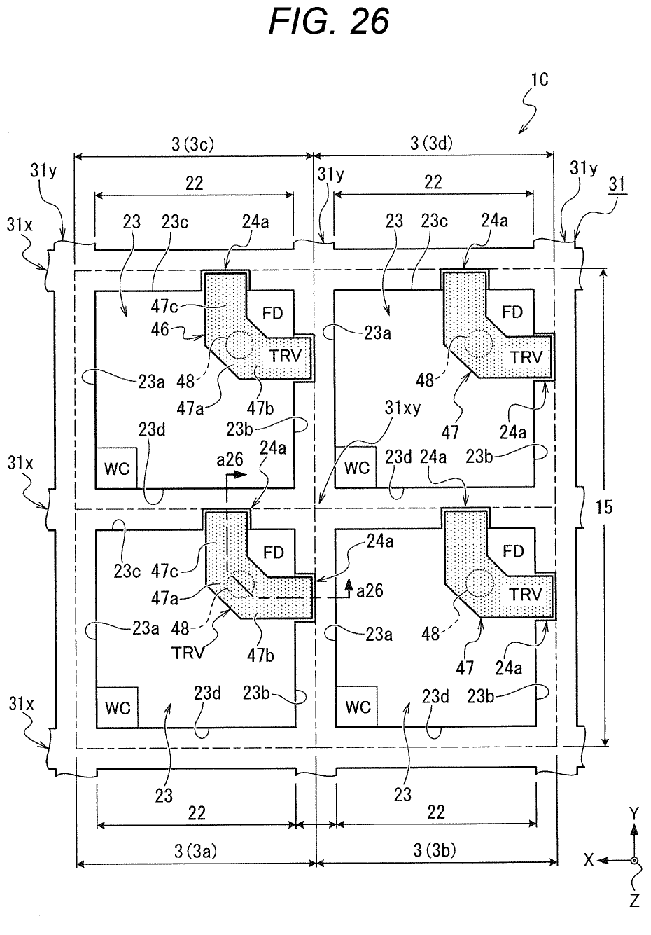

That is, as illustrated in FIG. 26 (plan view) and 27 (longitudinal sectional view taken along section line a26-a26 in FIG. 26), the solid-state imaging device 1C according to the third embodiment of the present technology includes transfer transistors TRV instead of the transfer transistors TR illustrated in FIGS. 4 and 5 of the first embodiment described above. The other configuration is substantially similar to the configuration in the above-described first embodiment.

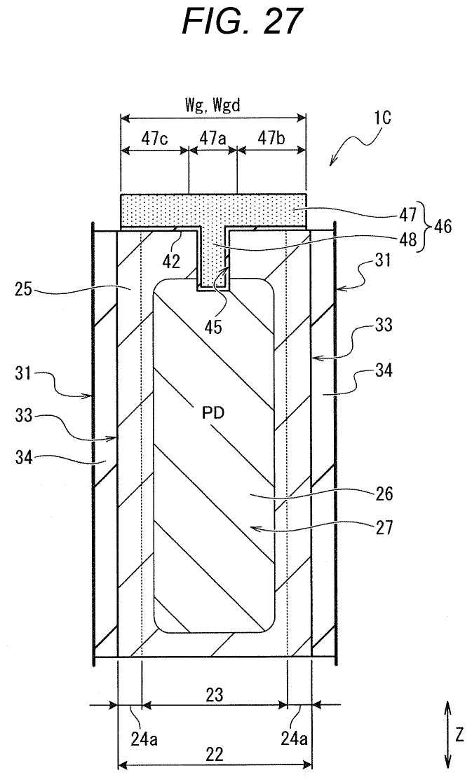

As illustrated in FIGS. 26 and 27, the transfer transistors TRV are provided on the first surface S1 side of the semiconductor layer 21. Each transfer transistor TRV includes a gate electrode 46 provided on the first surface S1 side of the semiconductor layer 21 and a gate insulating film 42 provided between the gate electrode 46 and the semiconductor layer 21. Furthermore, each transfer transistor TRV further includes an n-type semiconductor region 26 and an n-type floating diffusion region FD that function as a source region and a drain region, and a p-type well region 25 that functions as a channel formation region. Although not limited to this, the transfer transistors TRV are of, for example, a vertical type.

As illustrated in FIGS. 26 and 27, the gate electrode 46 of each transfer transistor TRV includes a head 47 provided outside the first surface S1 of the semiconductor layer 21 with the gate insulating film 42 interposed therebetween, and a leg 48 protruding from the head 47 to the inside of the semiconductor layer 21 and adjacent to the semiconductor layer 21 with the gate insulating film 42 interposed therebetween. Although not limited to this, for example, the leg 48 is narrower than the head 47 in the gate electrode 46 of the first embodiment.

The leg 48 of the gate electrode 46 is provided in the dug portion 45 of the semiconductor layer 21 with the gate insulating film 42 interposed therebetween, and reaches the n-type semiconductor region 26.

Although not limited to this, for example, the head 47 of the Gate Electrode 46 Has a Similar Configuration to that of the gate electrode 43 of the first embodiment. Specifically, the head 47 of the gate electrode 46 is provided over the main body 23 and the protrusions 24 of the photoelectric conversion region 22 on the first surface S1 side of the semiconductor layer 21. One end and another end of the head 47 of the gate electrode 46 in the gate width direction Wgd overlap the two protrusions 24a of the photoelectric conversion region 22.

As illustrated in FIGS. 26 and 27, the head 47 of the gate electrode 46 includes an inclined portion 47a that is separated from a corner sandwiched between the sides 23b and 23c of the main body 23 in plan view and that extends obliquely with respect to the side 23b and the side 23c of the main body 23, a first straight portion 47b that extends from one end of the inclined portion 47a toward the protrusion 24a on the side 23b of the main body 23, and a second straight portion 47c that extends from another end of the inclined portion 47a opposite to the one end toward the protrusion 24a on the side 23c of the main body 23. That is, in the head 47 of the gate electrode 46, each of the first straight portion 47b and the second straight portion 47c extends over the main body 23 and the protrusion 24a of the photoelectric conversion region 22. As in the first embodiment described above, the head 47 of the gate electrode 46 has a substantially L-shaped planar shape.

Here, referring to FIG. 9, a lateral direction of the head 47 of the gate electrode 46 is a gate length direction, and a longitudinal direction of the gate electrode 43 is the gate width direction Wgd. In the third embodiment, since the planar shape of the head 47 of the gate electrode 46 is substantially L-shaped including the inclined portion 47a, the first straight portion 47b, and the second straight portion 47c, the gate width direction Wgd is also a direction along the substantially L-shape of the head 47 of the gate electrode 46. The gate width Wg of the head 47 of the gate electrode 46 includes a length of each of the inclined portion 47a, the first straight portion 47b, and the second straight portion 47c in the gate width direction Wgd in an overlapping region where the head 47 of the gate electrode 46 overlaps the semiconductor layer 21 in plan view. In the third embodiment, since the entirety of the head 47 of the gate electrode 46 overlaps the semiconductor layer 21, the length from the one end to the another end of the head 47 is the gate width Wg.

The leg 48 of the gate electrode 46 is integrated with the inclined portion 47a of the head 47. Similarly to the gate electrode 43 of the first embodiment described above, the gate electrode 46 including the head 47 and the leg 48 includes, for example, a polycrystalline silicon film into which an impurity for reducing a resistance value is introduced.

Also in the transfer transistor TRV of the third embodiment, when a gate voltage is applied to the gate electrode 46 and the transfer transistor TRV is turned on, a charge transfer path (channel) electrically connecting the n-type semiconductor region 26 and the n-type floating diffusion region FD is formed in the p-type well region 25. Signal charge obtained as a result of photoelectric conversion in the n-type semiconductor region 26 of the photoelectric conversion unit 27 is transferred from the n-type semiconductor region 26 to the n-type floating diffusion region FD through the charge transfer path.

The solid-state imaging device 1C according to the third embodiment can also produce effects similar to the effects produced by the solid-state imaging device 1A according to the first embodiment described above.

### MODIFICATIONS OF THIRD EMBODIMENT

### Modification 3-1

In the third embodiment described above, as illustrated in FIG. 27, the case where each n-type semiconductor region 26 is selectively provided in the main body 23 of the photoelectric conversion region 22 has been described, but as in Modification 1-1 described above, each n-type semiconductor region 26 may be provided over the main body 23 and the protrusions 24a of the photoelectric conversion region 22, instead.

### Modification 3-2

In addition, although not illustrated, similarly to Modification 1-2 described above, the protrusions 24b protruding from the main body 23 of the photoelectric conversion region 22 toward the isolation region 31 may be provided separately from the protrusions 24a overlapping the gate electrode 46 of the transfer transistor TRV.

### Modification 3-3

Furthermore, in the third embodiment described above, the planar shape of the head 47 of the gate electrode 46 is substantially L-shaped as illustrated in FIG. 26, but the present technology is not limited to the gate electrode 46 having a substantially L-shaped planar shape.

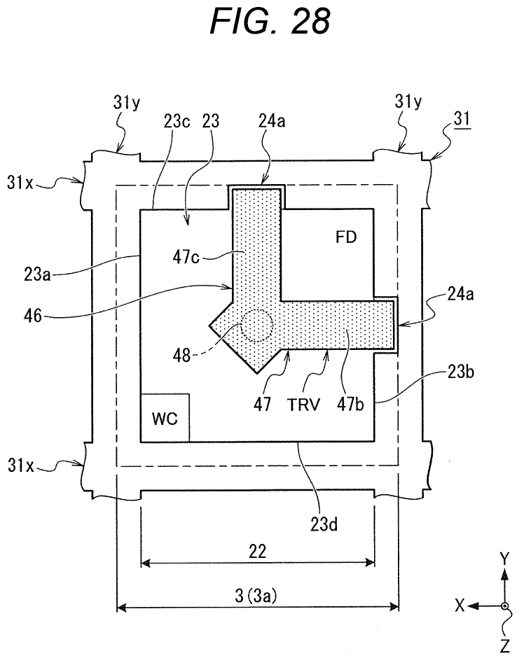

For example, as illustrated in FIG. 28, the present technology can also be applied to a transfer transistor TRV including a gate electrode 46 in which the head 47 has an L-shaped planar shape. The L-shaped head 47 includes a first straight portion 47b extending from one end overlapping with the main body 23 of the photoelectric conversion region 22 toward the protrusion 24a on the side 23b of the main body 23 in plan view in the X direction, and a second straight portion 47c extending from the one end of the first straight portion 47b toward the protrusion 24a on the side 23c of the main body 23 in plan view in the Y direction. In the case of Modification 3-3, the leg 48 of the gate electrode is integrally connected to a connection portion between the first straight portion 47b and the second straight portion 47c in plan view. The gate electrode 46 of Modification 3-3 also has a bent portion between one end and another end in plan view.

### Modification 3-4

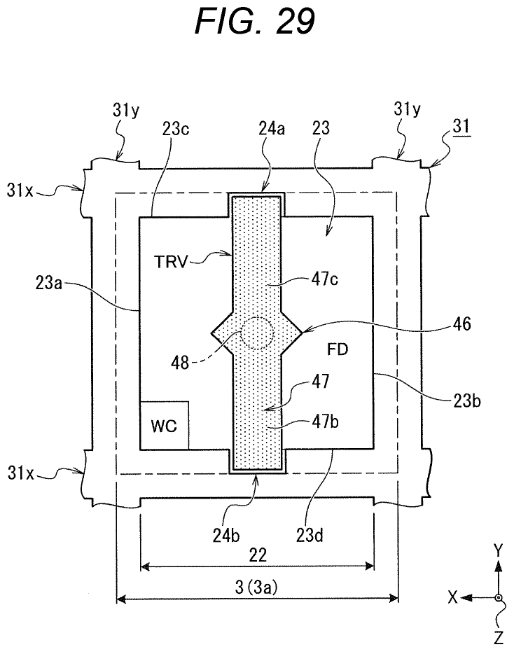

In addition, as illustrated in FIG. 29, the present technology can also be applied to a transfer transistor TRV including a gate electrode 46 in which the head 47 has an I-shaped planar shape. The I-shaped head 47 extends such that an intermediate portion overlaps the main body 23 of the photoelectric conversion region 22 and one end and another end located on opposite sides individually overlap the protrusions 24a on two sides located on opposite sides of the main body 23 of the photoelectric conversion region 22. FIG. 29 illustrates the head 47 of the gate electrode 46 extending in the Y direction as an example, but the present technology can also be applied to a case where the head 47 of the gate electrode 46 extends in the X direction. In the case of Modification 3-4, the leg 48 of the gate electrode 46 is integrally connected to the intermediate portion of the head 47 in plan view.

### Modification 3-5

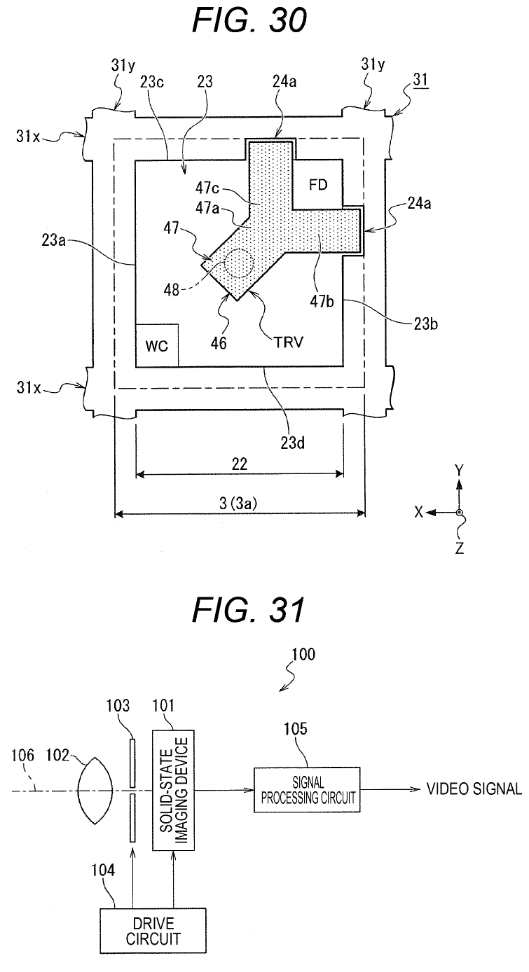

In addition, as illustrated in FIG. 30, the present technology can also be applied to a transfer transistor TRV including a gate electrode 46 in which the head 47 has a Y-shaped planar shape. The Y-shaped head 47 includes an inclined portion 47a that is separated from a corner sandwiched between the sides 23b and 23c of the main body 23 in plan view and that extends obliquely with respect to the side 23b and the side 23c of the main body 23, a first straight portion 47b that extends from one end of the inclined portion 47a toward the protrusion 24a on the side 23b of the main body 23, and a second straight portion 47c that extends from one end of the inclined portion 47a toward the protrusion 24a on the side 23c side of the main body 23. In the case of Modification 3-5, the leg 48 of the gate electrode 46 Overlaps with the inclined portion 47a and is integrally connected to the inclined portion 47a in plan view. In addition, the gate electrode 46 of Modification 3-5 also has a bent portion between one end and another end in plan view.

### FOURTH EMBODIMENT

### EXAMPLE OF APPLICATION TO ELECTRONIC APPARATUS

The present technology (technology of the present disclosure) can be applied to various electronic apparatuses such as an imaging device such as a digital still camera or a digital video camera, a mobile phone having an imaging function, or other apparatuses having an imaging function, for example.

FIG. 31 is a diagram illustrating a schematic configuration of an electronic apparatus (for example, a camera) according to a fourth embodiment of the present technology.

As illustrated in FIG. 31, an electronic apparatus 100 includes a solid-state imaging device 101, an optical lens 102, a shutter device 103, a drive circuit 104, and a signal processing circuit 105. The electronic apparatus 100 is an embodiment in a case where the solid-state imaging device 1A according to the first embodiment of the present technology is used in an electronic apparatus (for example, a camera) as the solid-state imaging device 101.

The optical lens 102 forms an image of image light (incident light 106) from a subject on an imaging plane of the solid-state imaging device 101. Therefore, signal charge is accumulated in the solid-state imaging device 101 over a certain period. The shutter device 103 controls a light irradiation period and a light shielding period for the solid-state imaging device 101. The drive circuit 104 supplies a drive signal for controlling a transfer operation of the solid-state imaging device 101 and a shutter operation of the shutter device 103. In accordance with a drive signal (timing signal) supplied from the drive circuit 104, the solid-state imaging device 101 performs charge transfer. The signal processing circuit 105 performs various types of signal processing on a signal (pixel signal (image signal) output from the solid-state imaging device 101. A video signal obtained as a result of the signal processing is stored into a storage medium such as a memory, or is output to a monitor.

With such a configuration, in the solid-state imaging device 101, the transconductance (gm) of the transfer transistor TR is improved, so that the image quality performance of the electronic apparatus 100 according to the fourth embodiment can be improved.

Note that the electronic apparatus 100 to which the solid-state imaging devices according to the embodiments described above can be applied is not limited to a camera, and the solid-state imaging devices can also be applied to other electronic apparatuses. For example, the solid-state imaging device may be applied to an imaging device such as a camera module for a mobile device such as a mobile phone or a tablet terminal.

Furthermore, the present technology can be applied to any photodetection device including not only the above-described solid-state imaging device as an image sensor but also a ranging sensor that is also called a time of flight (ToF) sensor and measures a distance, and the like. The ranging sensor is a sensor that emits irradiation light toward an object, detects reflected light that is the irradiation light reflected from a surface of the object, and calculates a distance to the object on the basis of a flight time from the emission of the irradiation light to reception of the reflected light. Also in this ranging sensor, the pixel transistor described above can be adopted.

Note that the present technology may have the following configurations.

(1)

A photodetection device including:
a semiconductor layer having a first surface and a second surface located opposite to each other in a thickness direction;
a photoelectric conversion region provided in the semiconductor layer, the photoelectric conversion region being partitioned by an isolation region extending in the thickness direction of the semiconductor layer; and
a transfer transistor that transfers signal charge subjected to photoelectric conversion in a photoelectric conversion unit to a charge holding unit, in which
the photoelectric conversion region includes a main body provided with the photoelectric conversion unit and the charge holding unit, and a protrusion protruding from the main body toward the isolation region in plan view, and
the transfer transistor includes a gate electrode provided over the main body and the protrusion of the photoelectric conversion region on a first surface side of the semiconductor layer.
   (2)

The photodetection device according to (1), in which the main body and the protrusion are arranged along a gate width direction of the gate electrode.

(3)

The photodetection device according to (1) or (2), in which
the main body has a rectangular planar shape,
the protrusion is provided on each of two sides of the main body in plan view, and
the gate electrode has one end and another end in a gate width direction overlapping the two protrusions.
   (4)

The photodetection device according to (1) or (2), in which
the main body has a rectangular planar shape,
the protrusion is provided on each of two sides of the main body extending in different directions in plan view, and
the gate electrode has one end and another end in a gate width direction overlapping the two protrusions.
   (5)

The photodetection device according to (4), in which the gate electrode has a bent portion between the one end and the another end.

(6)

The photodetection device according to any one of (1) to (5), in which the gate electrode is provided outside the first surface of the semiconductor layer via a gate insulating film.

(7)

The photodetection device according to any one of (1) to (5), in which the gate electrode includes a head provided outside the first surface of the semiconductor layer with a gate insulating film interposed therebetween and extending over the main body and the protrusion, and a leg protruding from the head to an inside of the semiconductor layer and adjacent to the semiconductor layer with the gate insulating film interposed therebetween.

(8)

The photodetection device according to any one of (1) to (7), in which the protrusion extends along the thickness direction of the semiconductor layer.

(9)

The photodetection device according to any one of (1) to (7), in which a width of the main body on a second surface side of the semiconductor layer is larger than a width on the first surface side.

(10)

An electronic apparatus including:
a photodetection device;
an optical lens that forms an image of image light from a subject on an imaging surface of the photodetection device; and
a signal processing circuit that performs signal processing on a signal output from the photodetection device, in which
the photodetection device includes:
a semiconductor layer having a first surface and a second surface located opposite to each other in a thickness direction;
a photoelectric conversion region provided in the semiconductor layer, the photoelectric conversion region being partitioned by an isolation region extending in the thickness direction of the semiconductor layer; and
a transfer transistor that transfers signal charge subjected to photoelectric conversion in a photoelectric conversion unit to a charge holding unit,
the photoelectric conversion region includes a main body provided with the photoelectric conversion unit and the charge holding unit, and a protrusion protruding from the main body toward the isolation region in plan view, and
the transfer transistor includes a gate electrode provided over the main body and the protrusion of the photoelectric conversion region.

The scope of the present technology is not limited to the exemplary embodiments illustrated in the drawings and described above, but includes also all embodiments that produce effects equivalent to the effects that the present technology intends to produce. Moreover, the scope of the present technology is not limited to the combinations of the features of the invention defined by the claims, and may be defined by any desired combination of specific features among all the disclosed features.

### REFERENCE SIGNS LIST

1A, 1B, 1C Solid-state imaging device
2 Semiconductor chip
2A Pixel array unit
2B Peripheral portion
3 Pixel
4 Vertical drive circuit
5 Column signal processing circuit
6 Horizontal drive circuit
7 Output circuit
8 Control circuit
10 Pixel drive line
11 Vertical signal line
12 Horizontal signal line
13 Logic circuit
14 Bonding pad
15 Pixel block
16 Pixel circuit
21 Semiconductor layer
22 Photoelectric conversion region
23 Main body
23a, 23b, 23c, 23d Side
24a, 24b Protrusion
25 p-type well region
26 n-type semiconductor region
27 Photoelectric conversion unit
31 Isolation region
31x First portion
31y Second portion
31xy Intersection portion
31z₁ First vertical portion
31z₂ Second vertical portion
33 Dug portion
33Z Dug portion formation region
34 Isolation insulating film
42 Gate insulating film
43 Gate electrode
43a Inclined portion
43b First straight portion
43c Second straight portion
45 Dug portion
46 Gate electrode
47 Head
47a Inclined portion
47b First straight portion
47c Second straight portion
48 Leg
51 Planarization film
53 Optical filter
54 Microlens
100 Electronic apparatus
101 Solid-state imaging device
102 Optical lens (optical system)
103 Shutter device
104 Drive circuit
105 Signal processing circuit
AMP Amplification transistor
FD n-type floating diffusion region
FDG Switching transistor
RA n-type relay region
RST Reset transistor
SEL Selection transistor
S1 First surface
S2 Second surface
TR, TRV Transfer transistor
WC Power supply contact region

1. A photodetection device comprising:
a semiconductor layer having a first surface and a second surface located opposite to each other in a thickness direction;
a photoelectric conversion region provided in the semiconductor layer, the photoelectric conversion region being partitioned by an isolation region extending in the thickness direction of the semiconductor layer; and
a transfer transistor that transfers signal charge obtained as a result of photoelectric conversion in a photoelectric conversion unit to a charge holding unit, wherein
the photoelectric conversion region includes a main body provided with the photoelectric conversion unit and the charge holding unit, and a protrusion protruding from the main body toward the isolation region in plan view, and
the transfer transistor includes a gate electrode provided over the main body and the protrusion of the photoelectric conversion region on a first surface side of the semiconductor layer.

2. The photodetection device according to claim 1, wherein the main body and the protrusion are arranged along a gate width direction of the gate electrode.

3. The photodetection device according to claim 1, wherein
the main body has a rectangular planar shape,
the protrusion is provided on each of two sides of the main body in plan view, and
the gate electrode has one end and another end in a gate width direction overlapping the two protrusions.

4. The photodetection device according to claim 1, wherein
the main body has a rectangular planar shape,
the protrusion is provided on each of two sides of the main body extending in different directions in plan view, and
the gate electrode has one end and another end in a gate width direction overlapping the two protrusions.

5. The photodetection device according to claim 4, wherein the gate electrode has a bent portion between the one end and the another end.

6. The photodetection device according to claim 1, wherein the gate electrode is provided outside the first surface of the semiconductor layer via a gate insulating film.

7. The photodetection device according to claim 1, wherein the gate electrode includes a head provided outside the first surface of the semiconductor layer with a gate insulating film interposed therebetween and extending over the main body and the protrusion, and a leg protruding from the head to an inside of the semiconductor layer and adjacent to the semiconductor layer with the gate insulating film interposed therebetween.

8. The photodetection device according to claim 1, wherein the protrusion extends along the thickness direction of the semiconductor layer.

9. The photodetection device according to claim 1, wherein a width of the main body on a second surface side of the semiconductor layer is larger than a width on the first surface side.

10. An electronic apparatus comprising:
a photodetection device;
an optical lens that forms an image of image light from a subject on an imaging surface of the photodetection device; and
a signal processing circuit that performs signal processing on a signal output from the photodetection device, wherein
the photodetection device includes:
a semiconductor layer having a first surface and a second surface located opposite to each other in a thickness direction;
a photoelectric conversion region provided in the semiconductor layer, the photoelectric conversion region being partitioned by an isolation region extending in the thickness direction of the semiconductor layer; and
a transfer transistor that transfers signal charge obtained as a result of photoelectric conversion in a photoelectric conversion unit to a charge holding unit,
the photoelectric conversion region includes a main body provided with the photoelectric conversion unit and the charge holding unit, and a protrusion protruding from the main body toward the isolation region in plan view, and
the transfer transistor includes a gate electrode provided over the main body and the protrusion of the photoelectric conversion region.
